(19) United States
(12) Patent Application Publication
(10) Pub. No.: US 2025/0328085 A1
(43) Pub. Date: Oct. 23, 2025

(54) METHOD AND APPARATUS FOR DETERMINING A PHYSICAL QUANTITY

(71) Applicant: ASML Netheriands B.V., Veldhoven (NL)

(72) Inventors: Michael Alphons Theodorus VAN HINSBERG, Eindhoven (NL); Antonius Johannes KAATS, Nederwetten (NL); James Robert DOWNES, Eindhoven (NL); Mark-Jan SPIJKMAN, Eindhoven (NL); Roberto PAGANO, Breda (NL)

(73) Assignee: ASML Netheriands B.V., Veldhoven (NL)

(21) Appl. No.: 18/870,300

(22) PCT Filed: May 23, 2023
(86) PCT No.: PCT/EP2023/063729

§ 371 Date: Nov. 27, 2024

(30) Foreign Application Priority Data
Jun. 23, 2022 (EP) 22180704.3

(51) Int. Cl. G03F 7/00; G01M 11/02

(52) U.S. Cl. CPC G03F 7/706; G01M 11/0271; G03F 7/70158; G03F 7/70508; G03F 7/70525; G03F 7/706837; G03F 7/706849; G03F 7/706851; G03F 7/7085; G03F 7/70991

(57) ABSTRACT

A method of determining a physical quantity is disclosed. The method uses a sensor system configured to sample a plurality of positions in parallel, wherein sampling each position uses radiation incident on an object plane patterning device (mark) and an image plane sensor. Each mark comprises a first portion and a second portion, the first portion being different to the second portion, and wherein the first and second portions of at least one of the marks is transposed relative to the first and second portions of the other marks. Each mark corresponds to a different sampling position. The method comprises, for each portion of each mark: performing a first measurement in a first direction; and performing a second measurement in a second direction different to the first direction. Four data sets are determined and subsequently combined to determine the physical parameter.

### CROSS-REFERENCE TO RELATED APPLICATION

The application claims priority of EP application 22180704.3 which was filed on 23 Jun. 2022 and which is incorporated herein in its entirety by reference.

### FIELD

The present invention relates to a method of determining one or more physical quantities and associated apparatus for carrying out the method. The one or more physical quantities may relate to e.g. alignment between an object plane and an image plane of the projection system.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

In a lithographic apparatus, many sensor systems are used to measure all kinds of physical quantities. Examples of interesting quantities are distance/position, time, speed, acceleration, force, lens aberration, etc. Some of these sensor systems use a detector that outputs a periodically varying signal. Such a periodically varying signal may be obtained using a periodic structure, such as a grating. The periodic varying signal may have, for instance, a sinusoidal shape.

Radiation that has been patterned by the patterning device is focused onto the substrate using a projection system. The projection system may introduce optical aberrations, which cause the image formed on the substrate to deviate from a desired image (for example a diffraction limited image of the patterning device). Alignment in a lithographic apparatus is also an important aspect, e.g. to make sure the desired image is positioned in the correct position. Further alignment of components including e.g. a substrate is also an important aspect.

It may be desirable to provide methods and apparatus for accurately determining such physical quantities, for example aberrations caused by a projection system such that these aberrations can be better controlled, or the intensity of signal to determine e.g. substrate alignment. Furthermore, it may be desirable to provide methods and apparatus for accurately determining projection alignment in a lithographic apparatus.

### SUMMARY

According to a first aspect of the disclosure there is provided a method of determining a physical quantity, the method using a sensor system configured to sample a plurality of positions, wherein sampling at each position uses an object plane patterning device and an image plane sensor, wherein each object plane patterning device comprises a first portion and a second portion, the first portion being different to the second portion, and wherein the first and second portions of at least one of the object plane patterning devices are transposed relative to the first and second portions of the other object plane patterning devices; and wherein the method comprises: using the first portion of each object plane patterning device and performing a first measurement in a first direction so as to generate a first data set; using the second portion of each object plane patterning device and performing a second measurement in the first direction so as to generate a second data set; using the first portion of each object plane patterning device and performing a third measurement in a second direction so as to generate a third data set, the second direction being different to the first direction; using the second portion of each object plane patterning device and performing a fourth measurement in the second direction so as to generate a fourth data set; and combining the first, second, third and fourth data sets so as to determine the physical quantity.

The method according to the first aspect is advantageous as it results in the determined physical quantity being less sensitive to correlated intensity noise, as now discussed.

It will be appreciated that each of the first, second, third and fourth data sets is generated using radiation and that the radiation may be subject to intensity noise (i.e. the intensity of the radiation will be subject to variations or fluctuations over time). Radiation having a common noise source is incident on each object plane patterning device and the image plane sensor to generate the first, second, third and/or fourth data sets. Since the data generated within any one of the first, second, third and fourth data sets is formed with the same emission of radiation (e.g. continuous or pulsed) there will be a correlation in the intensity noise within any one of the first, second, third and fourth data sets.

The object plane patterning device may comprise a grating.

The orientation of the first portion of the object plane patterning device may be orthogonal to the orientation of the second portion. This arrangement is advantageous in view of minimizing the processing of data required for subsequent modelling.

The orientation of the at least one object plane patterning device may be orthogonal to the second orientation of the other object plane patterning devices.

In some embodiments, the first, second, third and fourth measurements form part of a shearing interferometry process.

In some embodiments, the first portion of the object plane patterning device has a first shearing direction and the second portion has a second shearing direction, the second shearing direction being different from the first shearing direction. The first direction of the first measurement may comprise a component parallel to the first shearing direction and a component parallel to the second shearing direction, and the second direction of the second measurement may comprise a component parallel to the first shearing direction and a component parallel to the second shearing direction. Where each of the first and second directions comprises a component parallel to the first shearing direction and a component parallel to the second shearing direction, scanning in either of the first and second directions effectively results in scanning in both the first and second shearing directions simultaneously.

In an embodiment, one of the first and second directions is such that a sign of its component parallel to the first shearing direction is opposite to a sign of its component parallel to the second shearing direction and the other one of the first and second directions is such that a sign of its component parallel to the first shearing direction is the same as a sign of its component parallel to the second shearing direction. Advantageously, when scanning in one direction, it can be ensured that the sign of the errors in the differential of the wavefront map in the other direction is different for each of the first and second sets. In turn, this allows correlated intensity errors to be modelled away. The first and second directions may be aligned at 45° relative to each of the first shearing direction and the second shearing direction.

In some embodiments, the image sensor may comprise a plurality of image sensors. Each of the plurality of image plane sensors may comprise a second patterning device positionable to receive radiation from a corresponding one of the plurality of object plane patterning devices, and wherein the plurality of image plane sensors comprises a detector arranged to receive radiation from the plurality of second patterning devices.

In some embodiments, the method of combining the first, second, third and fourth data sets so as to determine the physical quantity comprises: combining the first data set and the second data set so as to determine for each sampled position at least one first physical parameter; combining the third data set and the fourth data set so as to determine for each sampled position at least one second physical parameter; and
combining the determined first physical parameter for each sampled position and the determined second physical parameter for each sampled position to form an output corrected physical parameter for each sampled position so as to at least partially correct for errors in the determined first and second physical parameters caused by intensity variations in the radiation used to generate the first, second, third and/or fourth data sets.

The physical quantity may comprise one or more aberrations of a projection system. Further, the first, second, third and fourth physical parameters may respectively correspond to first, second, third and fourth aberration coefficients.

In some embodiments, combining the first data set and the second data set so as to determine one or more aberrations may further comprise: determining a first wavefront tilt coefficient in the first direction; and the step of combining the third data set and the fourth data set so as to determine one or more aberrations may further comprise: determining a second wavefront tilt coefficient in the first direction; and combining the determined first wavefront tilt coefficients in the first direction for each sampled position and the determined second wavefront tilt coefficients in the first direction for each sampled position so as to form an output wavefront tilt coefficient in the first direction for each sampled position so as to at least partially correct for errors in the determined first wavefront tilt coefficients in the first direction and the determined second wavefront tilt coefficients in the first direction caused by intensity variations in the radiation used to generate the first data set and the second data set.

In some embodiments, combining the determined first wavefront tilt coefficients in the first direction for each sampling position and the determined second wavefront tilt coefficients in the first direction for each sampling position so as to form an output wavefront tilt coefficient in the first direction for each sampling position may comprise: performing a least squares fit to simultaneously minimise: the root mean square for each sampling position of the difference between: (a) the determined first wavefront tilt coefficients in the first direction; and (b) the output wavefront tilt coefficient in the first direction plus a first constant; and the root mean square for each sampling position of the difference between: (a) the determined second wavefront tilt coefficients in the first direction; and (b) the output wavefront tilt coefficient in the first direction plus a second constant multiplied by +1 for the first portions of the grating structures of the object plane patterning devices and multiplied by −1 for the second portions of the grating structures of the object plane patterning devices.

In some embodiments the physical quantity comprises an intensity.

In some embodiments the physical quantity comprises one or more intensities of a measured radiation, and the first, second, third and fourth physical parameters respectively correspond to first, second, third and fourth intensity values.

In some embodiments combining the first, second, third and fourth data sets so as to determine the physical quantity comprises: combining the first data set and the second data set so as to, for each sampling position, determine a first wavefront tilt coefficient in the second stepping direction; combining the third data set and the fourth data set so as to, for each sampling position, determine a second wavefront tilt coefficient in the second direction; and combining the determined first wavefront tilt coefficients in the second direction for each sampling position and the determined second wavefront tilt coefficients in the second direction for each sampling position so as to form an output wavefront tilt coefficient in the second direction for each sampling position so as to at least partially correct for errors in the determined first wavefront tilt coefficients in the second direction and the determined second wavefront tilt coefficients in the second direction caused by intensity variations in the radiation used to generate the second data set and the fourth data set.

In some embodiments combining the determined first wavefront tilt coefficients in the second direction for each sampling position and the determined second wavefront tilt coefficients in the second direction for each sampling position so as to form an output wavefront tilt coefficient in the second direction for each sampling position comprises: performing a least squares fit so as to simultaneously minimise: the root mean square for the plurality sampling positions of the difference between: (a) the determined first wavefront tilt coefficients in the second direction; and (b) the output wavefront tilt coefficient in the second direction plus a third constant; and the root mean square for the plurality of sampling positions of the difference between: (a) the determined second wavefront tilt coefficients in the second direction; and (b) the output wavefront tilt coefficient in the second direction plus a fourth constant multiplied by +1 for the first portions of the grating structures of the object plane patterning devices of multiplied by −1 for the second portions of the grating structures of the object plane patterning devices.

In some embodiments, each measurement comprises: illuminating the plurality of object plane patterning devices with first radiation; forming, an image of each of the plurality of object plane patterning devices on a patterning device of a different one of the plurality of image plane sensors; scanning at least one of the plurality of object plane patterning devices or the corresponding plurality of image plane sensors through a plurality of positions separated in a direction so as to generate an oscillating phase-scanning signal for each of the plurality of sampling positions; and determining a phase of a harmonic of the oscillating signal at a plurality of positions on a radiation detector.

The harmonic of the oscillating signal, which is equated to a difference in the aberration map between a pair of positions in a pupil plane of a projection system at each of the plurality of positions on the radiation detector, may be a first harmonic.

The pair of positions in the pupil plane of the projection system may be separated in a shearing direction by a shearing distance which corresponds to twice the distance in the pupil plane between two adjacent first diffraction beams.

According to a second aspect of the disclosure there is a measurement system for determining a physical quantity, the measurement system comprising: a plurality of object plane patterning devices comprising a first set of patterning devices having a first orientation; and a second set of patterning devices having a second orientation, the second orientation being different to the first orientation; an illumination system arranged to illuminate the first and second sets of object plane patterning devices with radiation so as to form a plurality of first diffraction beams, the first diffraction beams from each of the first set of patterning devices being separated in a modulation direction corresponding to the first orientation and the first diffraction beams from each of the second set of patterning devices being separated in a modulation direction corresponding to the second orientation; an image plane sensor comprising a patterning device and a radiation detector; the illumination system being configured to form an image of each of the plurality of object plane patterning devices on the patterning device of the image plane sensor so as to form a plurality of second diffraction beams from each of the first diffraction beams; a positioning apparatus configured to move the plurality of object plane patterning devices in a first direction or a second direction; and a controller configured to carry out the method according to the invention.

According to a third aspect of the disclosure there is a measurement system for determining a physical quantity, the measurement system comprising: a plurality of object plane patterning devices comprising: a first set of patterning devices having a first orientation; and a second set of patterning devices having a second orientation, the second orientation being different to the first orientation; an illumination system arranged to illuminate the plurality of object plane patterning devices with radiation so as to form a plurality of first diffraction beams, the first diffraction beams from each of the first set of patterning devices being separated in a modulation direction corresponding to the first orientation and the first diffraction beams from each of the second set of patterning devices being separated in a modulation direction corresponding to the second orientation; a plurality of image plane sensors, each comprising a patterning device and each in communication with a radiation detector; the illumination system being configured to form an image of each of the plurality of object plane patterning devices on the patterning device of the image plane sensor so as to form a plurality of second diffraction beams from each of the first diffraction beams; a positioning apparatus configured to move at least one of the plurality of object plane patterning devices or the corresponding plurality of image plane sensors in a first direction or a second direction; and a controller configured to carry out the method according to the invention.

According to a fourth aspect of the disclosure there is provided a computer readable medium carrying a computer program comprising computer readable instructions configured to cause a computer to carry out a method according to any one of the first, second and third aspects of the present disclosure.

According to a fifth aspect of the disclosure there is provided a computer apparatus comprising: a memory storing processor readable instructions, and a processor arranged to read and execute instructions stored in said memory, wherein said processor readable instructions comprise instructions arranged to control the computer to carry out the method according to any one the first, second and third aspects of the present disclosure.

According to a sixth aspect of the disclosure there is provided a lithographic apparatus comprising the measurement system of any one of the fourth and fifth aspects of the present disclosure.

According to a seventh aspect of the disclosure there is provided a metrology tool comprising the measurement system of any one of the fourth and fifth aspects of the present disclosure.

It will be appreciated that one or more aspects or features described above or referred to in the following description may be combined with one or more other aspects or features.

### BRIEF DESCRIPTION OF THE DRAWINGS

Embodiments of the invention will now be described, by way of example only, with reference to the accompanying schematic drawings, in which:

FIG. 1 depicts a lithographic apparatus;

FIG. 2 is a schematic illustration of a measurement system according to an embodiment of the disclosure;

FIGS. 3A and 3B are schematic illustrations of a patterning device and a sensor apparatus which may form part of the measurement system of FIG. 2;

FIG. 4 is a schematic illustration of a measurement system according to an embodiment of the invention, the measurement system comprising a first patterned region and a second patterned region, the first patterned region arranged to receive radiation and to form a plurality of first diffraction beams;

FIG. 5 shows another example of a measurement patterning device MA′ of the type shown in FIG. 3A which uses mixed marks for the object plane patterning devices;

FIG. 6 is a schematic flow diagram for a new method of determining one or more aberrations of a projection system according to an embodiment of the present disclosure;

FIG. 7 shows an example set of phase-scan measurements, which may be representative of data recorded during any of the four scanning processes of the method shown in FIG. 6;

FIG. 8A shows the intensity correlation for each of an exemplary seven field points represented by the object level patterning devices shown in FIG. 5 due to an intensity fluctuation (solid arrow) and the components of this intensity correlation in each of the two scan directions (dotted arrows) for the first measurement step of the method shown in FIG. 6;

FIG. 8B shows the intensity correlation for each of an exemplary seven field points represented by the object level patterning devices shown in FIG. 5 due to an intensity fluctuation (solid arrow) and the components of this intensity error in each of the two scan directions (dotted arrows) for the second measurement step of the method shown in FIG. 6;

FIG. 8C shows the intensity correlation for each of an exemplary seven field points represented by the object level patterning devices shown in FIG. 5 due to an intensity fluctuation (solid arrow) and the components of this intensity error in each of the two scan directions (dotted arrows) for the third measurement step of the method shown in FIG. 6;

FIG. 8D shows the intensity correlation for each of an exemplary seven field points represented by the object level patterning devices shown in FIG. 5 due to an intensity fluctuation (solid arrow) and the components of this intensity error in each of the two scan directions (dotted arrows) for the fourth measurement step of the method shown in FIG. 6; and

FIG. 9 shows an example set of sub-steps that may form the last step of the method shown in FIG. 6 (in which correlated intensity errors can be modelled away in the step of combining the first, second, third and fourth data sets S₁, S₂, S₃, S₄ so as to determine the physical quantity, which may be e.g. one or more aberrations of the projection system.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of a substrate. The term “light valve” can also be used in this context. Besides the classic mask (transmissive or reflective, binary, phase-shifting, hybrid, etc.), examples of other such patterning devices include a programmable mirror array and a programmable LCD array.

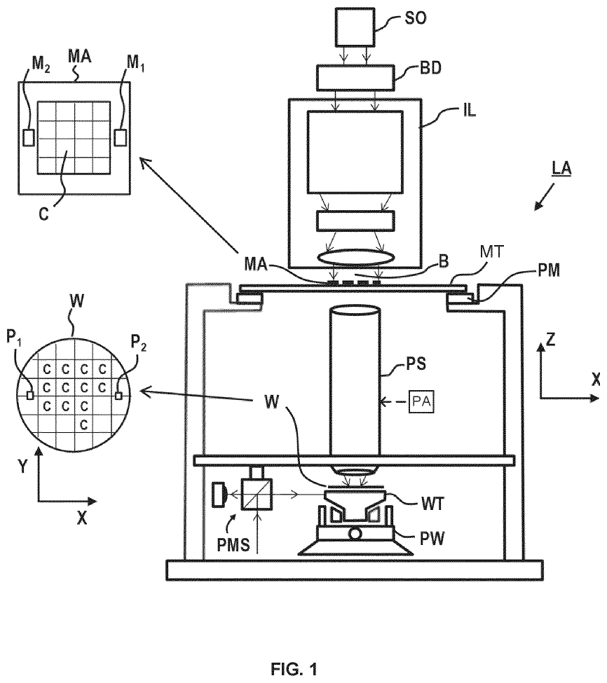

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W. It will be understood that projection system PS may be any system through which radiation from an illumination source is passed, through which defects may be acquired due to the failure of convergence of illumination-which can occur due to e.g. lens and/or mirror defects. As such, the patterning device may be located external to the kind of projection system PS as illustrated in FIG. 1, such that the radiation beam used for said patterning device is e.g. a metrology radiation beam and not for exposure of a pattern on the resist of a substrate.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the radiation being used—both for exposure and measurement—and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W-which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system PMS, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

The substrate W may include previously formed patterns. Where this is the case, the lithographic apparatus LA aligns the image, formed by the patterned radiation beam B, with a pattern previously formed on the substrate W.

To clarify the invention, a Cartesian coordinate system is used. The Cartesian coordinate system has three axes, i.e., an x-axis, a y-axis and a z-axis. Each of the three axis is orthogonal to the other two axes. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

Radiation used in the measurement and/or exposure systems of a lithography system, or in a metrology system such as an e-beam metrology tool, may be subject to intensity noise (i.e. the intensity of the radiation will be subject to variations or fluctuations over time). Such noise is detrimental to the accuracy of measurements or exposures. The present disclosure is directed to methods and associated apparatus to at least partially correct for such noise.

The projection system PS of a lithography system has an optical transfer function which may be non-uniform, which can affect the pattern which is imaged on the substrate W. For unpolarized radiation such effects can be fairly well described by two scalar maps, which describe the transmission (apodization) and relative phase (aberration) of radiation exiting the projection system PS as a function of position in a pupil plane thereof. These scalar maps, which may be referred to as the transmission map and the relative phase map, may be expressed as a linear combination of a complete set of basis functions. A particularly convenient set is the Zernike polynomials, which form a set of orthogonal polynomials defined on a unit circle. A determination of each scalar map may involve determining the coefficients in such an expansion. Since the Zernike polynomials are orthogonal on the unit circle, the Zernike coefficients may be obtained from a measured scalar map by calculating the inner product of the measured scalar map with each Zernike polynomial in turn and dividing this by the square of the norm of that Zernike polynomial. In the following, unless stated otherwise, any reference to Zernike coefficients will be understood to mean the Zernike coefficients of a relative phase map (also referred to herein as an aberration map). It will be appreciated that in alternative embodiments other sets of basis functions may be used. For example some embodiments may use Tatian Zernike polynomials, for example for obscured aperture systems.

A wavefront aberration map represents distortions of a wavefront of light approaching a point in an image plane of the projection system PS from a spherical wavefront (as a function of position in the pupil plane or, alternatively, the angle at which radiation approaches the image plane of the projection system PS). As discussed, this wavefront aberration map W(x,y) may be expressed as a linear combination of Zernike polynomials:

$$W ( x , y ) = {\sum }_{n} {Z}_{n} \cdot {z}_{n} ( x , y ) \qquad ( 1 )$$

where x and y are coordinates in the pupil plane, zₙ(x,y) is the nth Zernike polynomial and Zₙ is a coefficient. It will be appreciated that in the following, Zernike polynomials and coefficients are labelled with an index which is commonly referred to as a Noll index. Therefore, zₙ(x,y) is the Zernike polynomial having a Noll index of n and Zₙ is a coefficient having a Noll index of n. The wavefront aberration map may then be characterized by the set of coefficients Zₙ in such an expansion, which may be referred to as Zernike coefficients.

It will be appreciated that only a finite number of Zernike orders are taken into account. Different Zernike coefficients of the phase map may provide information about different forms of aberration which are caused by the projection system PS. The Zernike coefficient having a Noll index of 1 may be referred to as the first Zernike coefficient, the Zernike coefficient having a Noll index of 2 may be referred to as the second Zernike coefficient and so on.

The first Zernike coefficient Z₁ relates to a mean value (which may be referred to as a piston) of a measured wavefront. The first Zernike coefficient may be irrelevant to the performance of the projection system PS and as such may not be determined using the methods described herein. The second Zernike coefficient Z₂ relates to the tilt of a measured wavefront in the x-direction. The tilt of a wavefront in the x-direction is equivalent to a placement in the x-direction. The third Zernike coefficient Z₃ relates to the tilt of a measured wavefront in the y-direction. The tilt of a wavefront in the y-direction is equivalent to a placement in the y-direction. The fourth Zernike coefficient Z₄ relates to a defocus of a measured wavefront. The fourth Zernike coefficient is equivalent to a placement in the z-direction. Higher order Zernike coefficients relate to other forms of aberration which are caused by the projection system (e.g. astigmatism, coma, spherical aberrations and other effects).

Throughout this description the term “aberrations” should be intended to include all forms of deviation of a wavefront from a perfect spherical wavefront. That is, the term “aberrations” may relate to the placement of an image (e.g. the second, third and fourth Zernike coefficients) and/or to higher order aberrations such as those which relate to Zernike coefficients having a Noll index of 5 or more. Furthermore, any reference to an aberration map for a projection system may include all forms of deviation of a wavefront from a perfect spherical wavefront, including those due to image placement.

The relative phase of the projection system PS in its pupil plane may be determined by projecting radiation from an object plane patterning device (i.e. a patterning device in the plane of the patterning device MA), through the projection system PS and using a shearing interferometer to measure a wavefront (i.e. a locus of points with the same phase). Such a shearing interferometer may comprise a diffraction grating, for example a two dimensional diffraction grating, in an image plane of the projection system (i.e. the substrate table WT) and a detector arranged to detect an interference pattern in a plane that is conjugate to a pupil plane of the projection system PS.

The projection system PS comprises a plurality of optical elements. The lithographic apparatus LA further comprises adjusting means PA for adjusting these optical elements so as to correct for aberrations (any type of phase variation across the pupil plane throughout the field). To achieve this, the adjusting means PA may be operable to manipulate optical elements within the projection system PS in one or more different ways. The projection system may have a co-ordinate system wherein its optical axis extends in the z direction (it will be appreciated that the direction of this z axis may change along the optical path through the projection system). The adjusting means PA may be operable to do any combination of the following: displace one or more optical elements; tilt one or more optical elements; and/or deform one or more optical elements. Displacement of optical elements may be in any direction (x, y, z or a combination thereof). Tilting of optical elements is typically out of a plane perpendicular to the optical axis, by rotating about axes in the x or y directions although a rotation about the z axis may be used for non-rotationally symmetric optical elements. Deformation of an optical element may be performed for example by using actuators to exert force on sides of the optical element and/or by using heating elements to heat selected regions of the optical element. In general, it may not be possible to adjust the projection system PS to correct for apodizations (transmission variation across the pupil plane). The transmission map of a projection system PS may be used when designing masks MAs for the lithographic apparatus LA.

In some embodiments, the adjusting means PA may be operable to move the support structure MT and/or the substrate table WT. The adjusting means PA may be operable to displace (in any of the x, y, z directions or a combination thereof) and/or tilt (by rotating about axes in the x or y directions) the support structure MT and/or the substrate table WT.

A projection system PS which forms part of a lithographic apparatus may periodically undergo a calibration process. For example, when a lithographic apparatus is manufactured in a factory the optical elements which form the projection system PS may be set up by performing an initial calibration process. After installation of a lithographic apparatus at a site at which the lithographic apparatus is to be used, the projection system PS may once again be calibrated. Further calibrations of the projection system PS may be performed at regular intervals. For example, under normal use the projections system PS may be calibrated every few months (e.g. every three months).

Calibrating a projection system PS may comprise passing radiation through the projection system PS and measuring the resultant projected radiation. Measurements of the projected radiation may be used to determine aberrations in the projected radiation which are caused by the projection system PS. Aberrations which are caused by the projection system PS may be determined using a measurement system. In response to the determined aberrations, the optical elements which form the projection system PS may be adjusted so as to correct for the aberrations which are caused by the projection system PS.

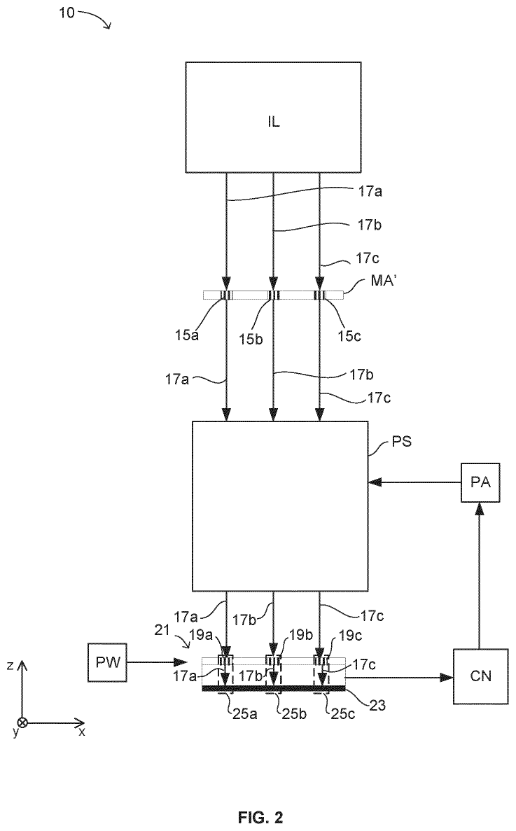

FIG. 2 is a schematic illustration of a measurement system 10 which may be used to determine aberrations which are caused by a projection system PS. The measurement system 10 comprises an illumination system IL, a measurement patterning device MA′, a sensor apparatus 21 and a controller CN. The measurement system 10 may form part of a lithographic apparatus. For example, the illumination system IL and the projection system PS which are shown in FIG. 2 may be the illumination system IL and projection system PS of the lithographic apparatus which is shown in FIG. 1. For ease of illustration additional components of a lithographic apparatus are not shown in FIG. 2.

The measurement patterning device MA′ is arranged to receive radiation from the illumination system IL. The sensor apparatus 21 is arranged to receive radiation from the projection system PS. During normal use of a lithographic apparatus, the measurement patterning device MA′ and the sensor apparatus 21 which are shown in FIG. 2 may be located in positions that are different to the positions in which they are shown in FIG. 2. For example, during normal use of a lithographic apparatus a patterning device MA which is configured to form a pattern to be transferred to a substrate W may be positioned to receive radiation from the illumination system IL and a substrate W may be positioned to receive radiation from the projection system PS (as is shown, for example, in FIG. 1). The measurement patterning device MA′ and the sensor apparatus 21 may be moved into the positions in which they are shown in FIG. 2 in order to determine aberrations which are caused by the projection system PS. The measurement patterning device MA′ may be supported by a support structure MT, such as the support structure which is shown in FIG. 1. The sensor apparatus 21 may be supported by a substrate table, such as the substrate table WT which is shown in FIG. 1. Alternatively the sensor apparatus 21 may be supported by a measurement table (not shown) which may be separate to the sensor table WT. It is to be understood that measurement system 10 may be applied to measure deviations of intensity in a metrology application rather than for aberration measurement of an exposure-based projection system.

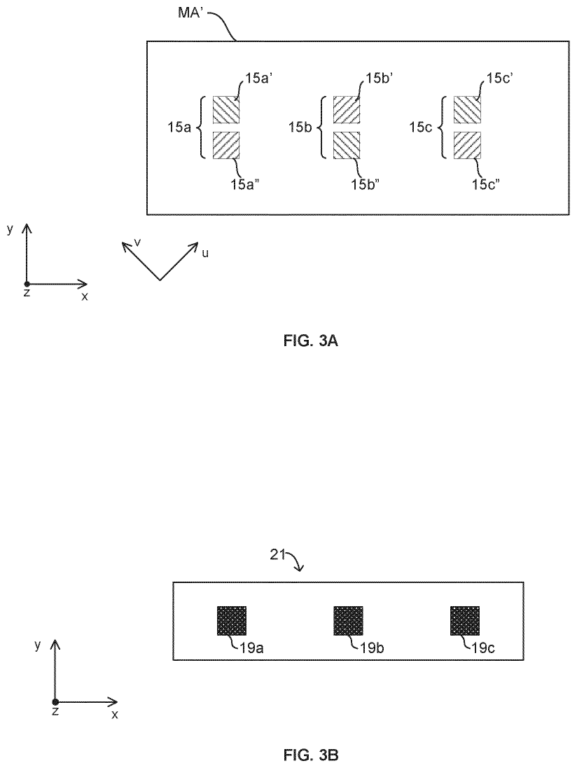

The measurement patterning device MA′ and the sensor apparatus 21 are shown in more detail in FIGS. 3A and 3B. FIG. 3A is a schematic illustration of the measurement patterning device MA′ in an x-y plane and FIG. 3B is a schematic illustration of the sensor apparatus 21 in an x-y plane.

The measurement patterning device MA′ comprises a plurality of patterned regions 15a-15c. Each of the plurality of patterned regions 15a-15c may be referred to as an object plane patterning device. In the embodiment which is shown in FIGS. 2 and 3A the measurement patterning device MA′ is a transmissive patterning device MA′. The patterned regions 15a-15c each comprises a transmissive diffraction grating. Radiation which is incident on the patterned regions 15a-15c of the measurement patterning device MA′ is at least partially scattered by thereby and received by, when used for aberration detection and alignment of a projection system, the projection system PS. In contrast, radiation which is incident on the remainder of the measurement patterning device MA′ is not transmitted towards the projection system PS (for example, it may be absorbed by the measurement patterning device MA′).

The illumination system IL illuminates the measurement patterning device MA′ with radiation. Whilst not shown in FIG. 2, the illumination system IL may receive radiation from a radiation source SO and condition the radiation so as to illuminate the measurement patterning device MA′. For example, the illumination system IL may condition the radiation so as to provide radiation having a desired spatial and angular distribution. In the embodiment which is shown in FIG. 2, the illumination system IL is configured to form separate measurement beams 17a-17c, each measurement beam 17a-17c illuminating a respective patterned region 15a-15c of the measurement patterning device MA′. In other embodiments, the illumination system IL may be configured to illuminate all of the patterned regions 15a-15c of the measurement patterning device MA′ with a single radiation beam (in such embodiments the plurality of measurement beams 17a-17c may be formed by the patterned regions 15a-15c).

In order to perform a determination of aberrations which are caused by the projection system PL, a mode of the illumination system IL may be changed in order to illuminate the measurement patterning device MA′ with separate measurement beams 17a-17c. For example, during normal operation of a lithographic apparatus, the illumination system IL may be configured to illuminate a patterning device MA with a slit of radiation. However the mode of the illumination system IL may be changed such that the illumination system IL is configured to form separate measurement beams 17a-17c in order to perform a determination of aberrations caused by the projection system PL. In some embodiments different patterned regions 15a-15c may be illuminated at different times. For example, a first subset of the patterned regions 15a-15c may be illuminated at a first time so as to form a first subset of measurement beams 17a-17c and a second subset of patterned regions 15a-15c may be illuminated at a second time so as to form a second subset of measurement beams 17a-17c.

In other embodiments the mode of the illumination system IL may be unchanged in order to perform a determination of aberrations caused by the projection system PL. For example, the illumination system IL may be configured to illuminate the measurement patterning device MA′ with a slit of radiation (e.g. which substantially corresponds with an illumination area used during exposure of substrates). Separate measurement beams 17a-17c may then be formed by the measurement patterning device MA′ since only the patterned regions 15a-15c transmit (and diffract) radiation towards the projection system PS.

In the Figures the Cartesian co-ordinate system is shown as being unchanged through the projection system PS. However, in some embodiments the properties of the projection system PS may lead to a transformation of the co-ordinate system. For example, the projection system PS may form an image of the measurement patterning device MA′ which is magnified, rotated and/or mirrored relative to the measurement patterning device MA′. In some embodiments the projection system PS may rotate an image of the measurement patterning device MA′ by approximately 180° around the z-axis. In such an embodiment the relative positions of a first measurement beam 17a and a third measurement beam 17c which are shown in FIG. 2, may be swapped at the sensor apparatus 21. In other embodiments the image may be mirrored about an axis which may lie in an x-y plane. For example, the image may be mirrored about the x-axis or about the y-axis.

In embodiments in which the projection system PS rotates an image of the measurement patterning device MA′ and/or the image is mirrored by the projection system PS, the projection system is considered to transform the co-ordinate system. That is, the co-ordinate system which is referred to herein is defined relative to an image which is projected by the projection system PS and any rotation and/or mirroring of the image causes a corresponding rotation and/or mirroring of the co-ordinate system. For ease of illustration, the co-ordinate system is shown in the Figures as being unchanged by the projection system PS. However, in some embodiments the co-ordinate system may be transformed by the projection system PS.

In the embodiment of FIG. 3A, each of a plurality of patterned regions 15a-15c comprises a first portion 15a′-15c′ and a second portion 15a″-15c″. The first and second portions of the patterned regions 15a-15c may be illuminated with the measurement beams 17a-17c at different times. For example, the first portions 15a′-15c′ of each of the patterned regions 15a-15c may be illuminated by the measurement beams 17a-17c at a first time. At a second time the second portions 15a″-15c″ of each of the patterned regions 15a-15c may be illuminated by the measurement beams 17a-17c. As was mentioned above in some embodiments different patterned regions 15a-15c may be illuminated at different times. For example, the first portions of a first subset of patterned regions 15a-15c may be illuminated at a first time and the first portions of a second subset of patterned regions 15a-15c may be illuminated at a second time. Second portions of the first and second subsets of patterned regions may be illuminated at the same or different times. In general any schedule of illuminating different portions of patterned regions 15a-15c may be used.

The plurality of object plane patterning devices 15a-15c shown in this embodiment comprises mixed patterning marks, as now explained. The term “mixed patterning marks” is a term of the art. Each of the plurality of object plane patterning devices 15a-15c comprises: a first portion 15a′-15c′ and a second portion 15a″-15c″, the first portions 15a′-15c′ being different to the second portions 15a″-15c″. The first and second portions of at least one of the plurality of object plane patterning devices is transposed relative to the first and second portions of the other object plane patterning devices. In the embodiment of FIG. 3A, it can be seen that object plane patterning device 15b is transposed relative to object plane patterning devices 15a and 15c. The at least one object plane patterning device 15b having transposed first 15a′ and second 15b″ portions relative to the other object plane patterning devices is known as a “mixed” patterning mark. In other words, the first and second portions of the at least one mixed patterning mark are flipped relative to the first and second portions of the other object plane patterning devices (which may be termed “unmixed patterning marks”), such that the orientation of the grating in the first portion 15b′ of the at least one mixed mark is different to the orientation of the grating in the first portion of the unmixed marks 15a′, 15c′. Similarly, the orientation of the grating in the second portion 15b″ of the at least one mixed mark is different to the orientation of the grating in the second portion of the unmixed marks 15a″, 15c″.

In the embodiment of FIG. 3A, the first portion 15a′ comprises a diffraction grating which is aligned parallel to a u-direction (and therefore has a shearing direction in the v-direction) and the second portion 15a″ comprises a diffraction grating which is aligned parallel to a v-direction (and therefore has a shearing direction in the u-direction). The first and second shearing directions are mutually perpendicular in this embodiment. The u and v-directions are both aligned at 45° relative to both the x and y-directions and are aligned perpendicular to each other. It will be appreciated that the orientation of the grating structures are not limited to shearing directions. The first and second orientations are preferably orthogonal to each other, but other relative orientations may be used. The direction of the scan, whether the scan is continuous or stepped (stepwise) relative to the grating direction, is not parallel, but is not limited to a 45° alignment—this is merely an example.

In use, the first portions of the object plane patterning devices 15a-15c will be illuminated together and, at another time, the second portions of the object plane patterning devices 15a-15c will be illuminated together. Therefore, with a patterning mark arrangement comprising mixed marks as shown in the embodiment shown in FIG. 3A, gratings having different orientations (in this embodiment, shearing directions) are illuminated simultaneously (when each of the first portions and the second portions are illuminated).

The modified measurement beams 17a-17c are received by the projection system PS. The projection system PS forms an image of the patterned regions 15a-15c on the sensor apparatus 21. The sensor apparatus 21 comprises a plurality of image plane sensors 25a-25c. Each of the plurality of image plane sensors 25a-25c comprises a second patterning device 19a-19c that is positionable so as to receive radiation from a corresponding one of the plurality of object plane patterning devices 15a-15c. Each of the second patterning devices 19a-19c comprises a diffraction grating 19a-19c. The plurality of image plane sensors 25a-25c further comprises a radiation detector 23 arranged to receive radiation from the plurality of second patterning devices 19a-19c. The diffraction gratings 19a-19c are arranged such that each diffraction grating 19a-19c receives a respective modified measurement beam 17a-17c which is output from the projection system PS. The modified measurement beams 17a-17c which are incident on the diffraction gratings 19a-19c are further modified by the diffraction gratings 19a-19c. The modified measurement beams which are transmitted at the diffraction gratings 19a-19c (from a corresponding one of the object plane patterning devices 15a-15c) are incident on the radiation detector 23.

In a first aberration measurement configuration, the plurality of object plane patterning devices 15a-15c and plurality of image plane sensors 25a-25c are positioned such that the projection system PS is arranged to form an image of the first portion 15a′-15c′ of each of the plurality of object plane patterning devices 15a-15c on a patterning device 19a-19c of a different one of the plurality of image plane sensors 25a-25c. At another time, in a second aberration measurement configuration, the plurality of object plane patterning devices 15a-15c and plurality of image plane sensors 25a-25c are positioned such that the projection system PS is arranged to form an image of the second portion 15a″-15c″ of each of the plurality of object plane patterning devices 15a-15c on a patterning device 19a-19c of a different one of the plurality of image plane sensors 25a-25c.

The radiation detector 23 is configured to detect the spatial intensity profile of radiation which is incident on the radiation detector 23. The radiation detector 23 may, for example, comprise an array of individual detector elements or sensing elements. For example, the radiation detector 23 may comprise an active pixel sensor such as, for example, a CMOS (complementary metal-oxide-semiconductor) sensor array. Alternatively, the radiation detector 23 may comprise a CCD (charge-coupled device) sensor array. The diffraction gratings 19a-19c and portions of the radiation sensor 23 at which the modified measurement beams 17a-17c are received form the image plane sensors 25a-25c. Each of the image plane sensors 25a-25c may be referred to as a detector region 25a-25c. For example, a first diffraction grating 19a and a first portion of the radiation sensor 23 at which a first measurement beam 17a is received together form a first image plane sensor (or detector region) 25a. A measurement of a given measurement beam 17a-17c may be made at a respective detector region 25a-25c (as depicted). As was described above, in some embodiments the relative positioning of the modified measurement beams 17a-17c and the co-ordinate system may be transformed by the projection system PS.

The modification of the measurement beams 17a-17c which occurs at the patterned regions 15a-15c and the diffraction gratings 19a-19c of the detector regions 25a-25c results in interference patterns being formed on the radiation detector 23. The interference pattern formed from each measurement beam is related to the derivative of the phase map in the orientation direction, e.g. shearing direction, of the grating used at the object level and depends on noise contributions due to e.g. aberrations caused by the projection system PS. The interference patterns may therefore be used to determine aberrations which are caused by the projection system PS.

In general, the diffraction gratings 19a-19c of each of the detector regions 25a-25c comprises a two-dimensional transmissive diffraction grating. In the embodiment which is shown in FIG. 3B the detector regions 25a-25c each comprise a diffraction grating 19a-19c which is configured in the form of a checkerboard. In alternative embodiments, the detector regions 25a-25c may each comprise a two-dimensional transmissive diffraction grating 19a-19c that is not configured in the form of a checkerboard although this may result in more complex interference pattern, which may be more difficult to derive an aberration map from. In further alternative embodiments, the detector regions 25a-c may each be a location on a single detector, and diffraction grating 19a-19c may be locations on a single diffraction grating 19, which may for example be in the form of a checkerboard.

Illumination of the first portions of the patterned regions 15a-15c may provide information related to a derivative of the relative phase map in a one direction and illumination of the second portions of the patterned regions 15a-15c may provide information related to a derivative of the relative phase map in another direction.

As described further below, in embodiments of the present disclosure, in each of the two measurement configurations to determine the physical quantity, the measurement patterning device MA′ and/or the sensor apparatus 21 is scanned continuously or stepwise in two perpendicular directions. For example, the measurement patterning device MA′ and/or the sensor apparatus 21 may be scanned relative to each other in each of the x and y-directions sequentially. It is to be noted that the x and y directions are merely exemplary and any two perpendicular directions may be used in order that each scan (measurement), which is in effect a partial scan, is mathematically orthogonal to the other and can thus be combined so as to create a full data set. Again, as described further below, in the first aberration measurement configuration, the measurement patterning device MA′ and/or the sensor apparatus 21 is scanned in a first direction (for example the y-direction) to generate a first phase-scanning data set and at another time is scanned in a second direction (for example the x-direction) to generate a second phase-scanning data set. In addition, in the second aberration measurement configuration, the measurement patterning device MA′ and/or the sensor apparatus 21 is scanned in the first direction (for example the y-direction) to generate a third phase-scanning data set and at another time is scanned in the second direction (for example the x-direction) to generate a fourth phase-scanning data set. Each of the first, second, third and fourth phase-scanning data sets are partial scan measurements. Taken alone, no useful measurement data is provided. The first, second, third and fourth phase-scanning data sets are combined so as to determine the physical quantity, which may be one or more aberrations of the projection system.

In each phase-scanning process, the measurement patterning device MA′ and/or the sensor apparatus 21 may be scanned and capture data separated by distances which correspond to a fraction of the grating period of the diffraction gratings. Measurements which are made at different scanning positions may be analysed in order to derive information about a derivative of a wavefront in the scanning direction. For example, the phase of the first harmonic of the measured signal (which may be referred to as a phase scanning signal) may contain information about the derivative of a wavefront in the shearing direction of the object plane grating. Since each of the plurality of object plane patterning devices 15a-15c comprises two portions having different orientations, e.g. different shearing directions, by illuminating each and performing a full phase-scanning process (i.e. a partial measurement scan in one direction combined with another partial measurement scan in a second direction), information about the wavefront can be derived in two different directions (in particular, it provides information about a derivative of the wavefront in each of the two shearing directions), thereby allowing the full wavefront to be reconstructed.

It will be appreciated that a variety of different arrangements of the patterned regions 15a-15c and the detector regions 25a-25c may be used in order to determine a physical quantity, such as aberrations caused by a projection system PS. The patterned regions 15a-15c and/or the detector regions 25a-25c may comprise diffraction gratings. In some embodiments the patterned regions 15a-15c and/or the detector regions 25a-25c may comprise components other than a diffraction grating. For example, in some embodiments the patterned regions 15a-15c and/or the detector regions may comprise a single slit or a pin-hole opening through which at least a portion of a measurement beam 17a-17c may propagate. In general the patterned regions and/or the detector regions may comprise any arrangement which serves to modify the measurement beams.

It will be further appreciated that the exemplary sensor system of FIG. 2 need not be limited to use in an exposure projection system PS, and also not to a shearing interferometry arrangement. For example, the patterned regions 15a-15c and the detector regions 25a-25c, and all embodiments thereof in this disclosure, may be used for intensity measurements using a dedicated metrology radiation source. Such a radiation source may be used, for example, to determine substrate alignment. It will be appreciated that the arrangement will be suitable for many different applications. Physical quantities such as intensity and error contributions thereof may also be determined, depending on the application of such a sensor arrangement.

The controller CN receives measurements made at the sensor apparatus 21 and determines, from the measurements, aberrations which are caused by the projection system PS. The controller may be configured to control one or more components of the measurement system 10. For example, the controller CN may control a positioning apparatus PW which is operable to move the sensor apparatus 21 and/or the measurement patterning device MA′ relative to each other. The controller may control an adjusting means PA for adjusting components of the projection system PS. For example, the adjusting means PA may adjust optical elements of the projection system PS so as to correct for aberrations which are caused by the projection system PS and which are determined by the controller CN.

In some embodiments, the controller CN may be operable to control the adjusting means PA for adjusting the support structure MT and/or the substrate table WT. For example, the adjusting means PA may adjust support structure MT and/or substrate table WT so as to correct for aberrations which are caused by placement errors of patterning device MA and/or substrate W (and which are determined by the controller CN).

Determining aberrations (which may be caused by the projection system PS or by placement errors of the patterning device MA or the substrate W) may comprise fitting the measurements which are made by the sensor apparatus 21 to Zernike polynomials in order to obtain Zernike coefficients. Different Zernike coefficients may provide information about different forms of aberration which are caused by the projection system PS. Zernike coefficients may be determined independently at different positions in the x and/or the y-directions. For example, in the embodiment which is shown in FIGS. 2, 3A and 3B, Zernike coefficients may be determined for each measurement beam 17a-17c.

In some embodiments the measurement patterning device MA′ may comprise more than three patterned regions, the sensor apparatus 21 may comprise more than three detector regions and more than three measurement beams may be formed. This may allow the Zernike coefficients to be determined at more field positions. In some embodiments the patterned regions and the detector regions may be distributed at different positions in both the x and y-directions. This may allow the Zernike coefficients to be determined at positions which are separated in both the x and the y-directions.

Whilst, in the embodiment which is shown in FIGS. 2, 3A and 3B the measurement patterning device MA′ comprises three patterned regions 15a-15c and the sensor apparatus 21 comprises three detector regions 25a-25c, in other embodiments the measurement patterning device MA′ may comprise more or less than three patterned regions 15a-15c and/or the sensor apparatus 21 may comprise more or less than three detector regions 25a-25c.

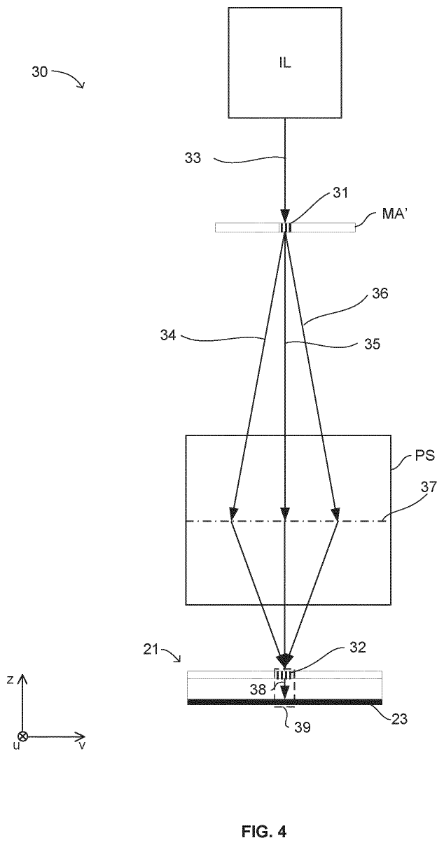

Methods for determining aberrations caused by a projection system PS are now described with reference to FIG. 4.

In general, measurement patterning device MA′ comprises at least one first patterned region 15a-15c and the sensor apparatus 21 comprises at least one corresponding second patterned region 19a-19c.

FIG. 4 is a schematic illustration of a measurement system 30 which may be used to determine aberrations which are caused by a projection system PS. Measurement system 30 may be the same as the measurement system 10 shown in FIG. 2, however, it may have a different number of first patterned regions (on measurement patterning device MA′) and second patterned regions (in the sensor apparatus 21). Therefore, the measurement system 30 shown in FIG. 4 may include any features of the measurement system 10 shown in FIG. 2 described above and these features will not be further described below.

In FIG. 4, only a single first patterned region 31 is provided on the measurement patterning device MA′ and a single second patterned region 32 is provided in the sensor apparatus 21.

The measurement patterning device MA′ is irradiated with radiation 33 from the illumination system IL. For ease of understanding only a single line (which may, for example, represent a single ray, for example the chief ray, of an incident radiation beam) is shown in FIG. 4. However, it will be appreciated that the radiation 33 will comprises a range of angles incident on the first patterned region 31 of the measurement patterning device MA′. That is, each point on the first patterned region 31 of the measurement patterning device MA′ may be illuminated by a cone of light. In general, each point is illuminated by substantially the same range of angles, this being characterized by the intensity of radiation in a pupil plane of the illumination system IL (not shown).

The first patterned region 31 is arranged to receive the radiation 33 and to form a plurality of first diffraction beams 34, 35, 36. A central first diffraction beam 35 corresponds to a 0^{th} order diffraction beam of first patterned region 31 and the other two first diffraction beams 34, 36 correspond to the ±1^{st} order diffraction beams of first patterned region 31. It will be appreciated that more, higher order diffraction beams will, in general, also be present. Again for ease of understanding, only three first diffraction beams 34, 35, 36 are shown in FIG. 4.

It will also be appreciated that, as the incoming radiation 33 comprises a cone of radiation converging on a point on the first patterned region 31, each of the first diffraction beams 34, 35, 36 also comprises a cone of radiation diverging from that point on the first patterned region 31.

To achieve the generation of the first diffraction beams 34, 35, 36, the first patterned region 31 may be of the form of a diffraction grating. For example, the first patterned region 31 may be generally of the form of the patterned region 15a shown in FIG. 3A. In particular, at least a portion of the first patterned region 31 may be of the form of the second portion 15a″ of the patterned region 15a shown in FIG. 3A, i.e. a diffraction grating which is aligned parallel to a u-direction and therefore having a shearing direction in the v-direction (note that FIG. 4 is shown in the z-v plane). Therefore, the first diffraction beams 34-36 are separated in a shearing direction, which is the v-direction.

The first diffraction beams 34-36 are at least partially captured by the projection system PS, as now described. How much of the first diffraction beams 34-36 is captured by the projection system PS will be dependent on: the pupil fill of the incident radiation 33 from the illumination system IL; the angular separation of the first diffraction beams 34-36 (which in turn is dependent on the pitch of the first patterned region 31 and the wavelength of the radiation 33); and the numerical aperture of the projection system PS.

The measurement system 30 may be arranged such that a first diffraction beam 35 that corresponds to the 0^{th} order diffraction beam substantially fills the numerical aperture of the projection system PS, which may be represented by a circular region of a pupil plane 37 of the projection system PS, and the first diffraction beams 34, 36 that correspond to the ±1^{st} order diffraction beams overlap significantly with the first diffraction beam 35 that corresponds to the 0^{th} order diffraction beam. With such an arrangement, substantially all of the first diffraction beam 35 that corresponds to the 0^{th} order diffraction beam and most of the first diffraction beams 34, 36 that correspond to the ±1^{st} order diffraction beams is captured by the projection system PS and projected onto the sensor apparatus 21. (Furthermore, with such an arrangement a large number of diffraction beams generated by the first patterned region 31 are at least partially projected onto the sensor apparatus 21).

The role of the first patterned region 31 is to introduce spatial coherence, as now discussed.

In general, two rays of radiation 33 from the illumination system IL that are incident on the same point of the measurement patterning device MA′ at different angles of incidence are not coherent. By receiving the radiation 33 and forming a plurality of first diffraction beams 34, 35, 36, the first patterned region 31 may be considered to form a plurality of copies of the incident radiation cone 33 (the copies having, in general different phases and intensities). Within any one of these copies, or first diffraction beams 34, 35, 36, two rays of radiation which originate from the same point on the measurement patterning device MA′ but at different scattering angles, are not coherent (due to the properties of the illumination system IL). However, for a given ray of radiation within any one of the first diffraction beams 34, 35, 36 there is a corresponding ray of radiation in each of the other first diffraction beams 34, 35, 36 that is spatially coherent with that given ray. For example, the chief rays
of each of the first diffraction beams 34, 35, 36 (which correspond to the chief ray of the incident radiation 33) are coherent and could, if combined, interfere at the amplitude level.

This coherence can be exploited by the measurement system 30 to determine an aberration map of the projection system PS.

The projection system PS projects part of the first diffraction beams 34, 35, 36 (which is captured by the numerical aperture of the projection system) onto the sensor apparatus 21.

In FIG. 4, the sensor apparatus 21 comprises the single second patterning region 32. As described further below, second patterned region 32 is arranged to receive these first diffraction beams 34-36 from the projection system PS and to form a plurality of second diffraction beams from each of the first diffraction beams. In order to achieve this, the second patterning region 32 comprises a two-dimensional transmissive diffraction grating. In FIG. 4, all radiation that is transmitted by the second patterning region 32 is represented as a single arrow 38. This radiation 38 is received by a detector region 39 of the radiation detector 23 and is used to determine the aberration map.

Each of the first diffraction beams 34-36 that is incident on the patterning region 32 will diffract to form a plurality of second diffraction beams. Since the second patterning region 32 comprises a two-dimensional diffraction grating, from each incident first diffraction beam, a two dimensional array of secondary diffraction beams is produced (the chief rays of these secondary diffraction beams being separated in both the shearing direction (e.g. the v-direction) and the direction perpendicular thereto (e.g. the u-direction). In the following, a diffraction order that is n^{th} order in the shearing direction (the v-direction) and m^{th} order in the non-shearing direction (the u-direction) will be referred to as the (n, m)^{th} diffraction order of the second patterned region 32. In the following, where it is not important what order a second diffraction beam is in the non-shearing direction (the u-direction), the (n, m)^{th} diffraction order of the second patterned region 32 may be referred to simply as the n^{th} order second diffraction beam.

Embodiments of the present disclosure relate to new methods for determining one or more physical quantities, for example, intensities to determine alignment of e.g. a substrate or wafer in a lithographic apparatus or in a metrology system, or aberrations (such as the tilt of the wavefront), of a projection system PS, as now discussed.

As used herein, the object (e.g. reticle) plane and the image (e.g. wafer) plane, and any other planes conjugate thereto, may be referred to as a field plane, or simply the field. With known methods, the physical quantities may be determined for a plurality of positions. For example, the aberrations of a projection system may be determined for a plurality of field points (i.e. points in a field plane of the projection system). For each position, which may be a field point, an object plane patterning device (mark) having two portions (each with a different orientation, which may for example be different shearing directions) and an image plane sensor is provided. The image sensor may be a corresponding plurality of image sensors. A first portion of the object plane patterning device (having a first orientation, e.g. a first shearing direction) is illuminated, and an image of that portion is formed on the image plane grating, optionally on a corresponding portion of the image plane grating. During illumination of the first portion, the object plane grating is scanned in a first direction, which may for example be a first shearing direction. In an embodiment where the image sensor is a corresponding plurality of image sensors and thus a plurality of image plane gratings, the image sensors may be scanned in the first direction instead of the object plane grating. In either case, scanning in the first direction during illumination generates a first set of phase-scanned data that is related to the physical quantity to be determined in the first direction, for example an intensity to determine alignment, or a gradient of the aberration map. Next, a second portion of the object plane patterning device (having a second orientation which may be a second shearing direction) is illuminated, and an image of that portion is formed on the image plane grating, which may be a corresponding image plane grating. During illumination of the second portion, at least one of the object plane grating and the image plane grating (where the image plane grating is a plurality of corresponding image plane gratings) is scanned in the second direction, which may be a second shearing direction. This generates second set of phase-scanned data that is related to the physical quantity in the second direction, e.g. a gradient of the aberration map. Each of the first and second phase-scanned data sets may be considered to be partial data sets, because when taken alone, no useful information can be derived therefrom. The first and second phase-scanned data are combined to determine the physical quantity, e.g. aberration (or relative phase) map of the projection system for that position, e.g. field point. Where the scan is performed as a continuous scan, the phase scan data may comprise data from a continuous scan across a discrete set of measurement points. An advantage of such a continuous scan is a faster measurement time. Where the scanning is performed as a stepwise measurement, the phase scan data comprises phase-stepped data across a number of points corresponding to the number of phase steps.

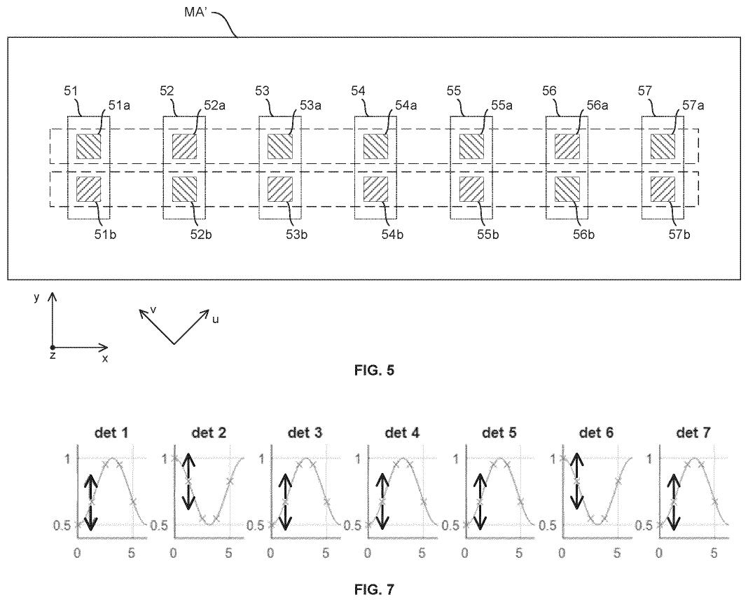

Embodiments of the present disclosure relate to a new method wherein physical quantities, e.g. aberrations are determined at a plurality of positions, e.g. field points. As with known methods, for each position or field point, an object plane patterning device (mark) having two portions (each with a different orientation, e.g. a different shearing direction) and an image plane sensor, which may be a corresponding image plane sensor for each object plane patterning device, is provided. As will be described below, in the new method, the object plane patterning devices (marks) comprise mixed marks having a mixture of first and second orientations, which may be first and second shearing directions, that are exposed simultaneously. The method comprises, for each portion of each mark: performing a first measurement, which may be a first continuous scanning measurement, a first stepwise measurement and/or a first shearing interferometry process using a first scanning direction; and performing a second measurement, which may be a second continuous scanning measurement, a second stepwise measurement and/or a second stepping shearing interferometry process using a second scanning direction. That is, each portion of the object plane patterning device is used for two phase scanning processes. The first and second scanning directions are different to the directions of the first and second grating orientations. Since there are two portions to each position mark and two scanning measurements are performed for each one, four data sets are determined. Therefore, four (rather than two) data sets are generated for each position, each position which may be a field point. These four determined data sets are combined so as to determine the physical quantity, which may be one or more aberrations of the projection system. This allows correlated intensity noise contributions to be modelled away, as now discussed with reference to FIGS. 5 to 9.

As stated above, the new method uses mixed marks for the object plane patterning devices (marks). For example, the method may use the measurement patterning device MA′ as shown in FIG. 3A and described above. Another example of a suitable measurement patterning device MA′ is shown in FIG. 5, which is now described.

The exemplary measurement patterning device MA′ comprises seven object plane patterning devices 51-57. This allows physical quantities such as aberrations to be determined at seven different positions (field points). It will be appreciated that in other embodiments, a different number of object plane patterning devices (and corresponding image plane sensors) may be provided.

Each of the plurality of object plane patterning devices 51-57 comprises: a first portion 51a-57a and a second portion 51b-57b. Within each object plane patterning device 51-57 one of the first and second portions 51a-57a, 51b-57b has a first shearing direction in the u-direction and the other one has a second shearing direction in the v-direction. The object plane patterning device orientations are not limited to shearing directions u and v, and will be described as such merely for illustrative purposes. Within the first object plane patterning device 51 the first portion 51a has a first shearing direction in the u-direction and the second portion 51b has a second shearing direction in the v-direction. Similarly, within the second object plane patterning device 52 the second portion 52b has a first shearing direction in the u-direction and the first portion 52a has a second shearing direction in the v-direction.

As will be described further below (with reference to FIG. 6), in the new method first portions 51a-57a of the object plane patterning devices 51-57 are illuminated simultaneously as part of a phase scanning process. Similarly, in the new method second portions 51b-57b of the object plane patterning devices 51-57 are illuminated simultaneously (but at a different time to the first portions 51a-57a).

The second shearing direction (v) is different to the first shearing direction (u). That is, the first and second shearing directions are lineally independent. In this example, the first and second shearing directions are mutually perpendicular although it will be appreciated that in other embodiments, the second shearing direction may be oriented at a different angles relative to the first shearing direction. In other embodiments, the grating structure orientations may not comprise shearing directions at all, but first orientation directions will be different relative to second orientation directions.

The plurality of object plane patterning devices 51-57 comprises: a first set of patterning devices 51, 53, 54, 55, 57 the first portion 51a, 53a, 54a, 55a, 57a of which has the first shearing direction (u); and a second set of patterning devices 52, 56 the first portion 52a, 56a of which having the second shearing direction (v).

The method further uses a seven image plane sensors, each one corresponding to a different one of the object plane patterning devices 51-57. Each of the image plane sensors is generally of the type of image plane sensor 25a-25c described above with reference to FIGS. 2 and 3B. Each of the image plane sensors comprises a second patterning device (of the type of second patterning device 19a-19c described above with reference to FIGS. 2 and 3B) which is positionable so as to receive radiation from a corresponding one of the plurality of object plane patterning devices 51-55. In alternative embodiments, a single image plane sensor may be used.

The image plane sensors further comprises a detector arranged to receive radiation from the plurality of second patterning devices (of the type of radiation sensor 23 described above with reference to FIG. 2).

The patterning device of each of the plurality of image plane sensors is arranged to receive first diffraction beams generated by a corresponding one of the plurality of object plane patterning devices 51-57 from the projection system PS and to form a plurality of second diffraction beams from each of the first diffraction beams.

In some embodiments a single detector may be provided which receives radiation from the one or more patterning devices of the one or more image plane sensors. Alternatively, in some embodiments each of the plurality of image plane sensors may be provided with a single detector.

Each of the plurality of object plane patterning devices 51-57 and the one or more patterning devices, which may be a corresponding one of the plurality of image plane sensors, may be matched such that at least some of the second diffraction beams formed from at least one of the first diffraction beams are spatially coherent with a second diffraction beam formed from at least one other first diffraction beam.

It will be appreciated that the matching of the object plane patterning devices 51-57 and the second patterning devices (such that at least some of the second diffraction beams formed from at least one of the first diffraction beams are spatially coherent with a second diffraction beam formed from at least one other first diffraction beam) may be achieved by matching the pitches of the object plane patterning device 51-57 and the corresponding second patterning device. It will be further appreciated that this matching of the pitches of the object plane patterning device 51-57 and the second patterning device takes into account any reduction factor applied by the projection system PS. Taking this into account, in general, the pitch of the second patterning device may be an integer multiple of the pitch of the object plane patterning device 51-57 or the pitch of the object plane patterning device 51-57 may be an integer multiple of the pitch of the second patterning device.

The detector may be referred to as a radiation detector. The radiation detector may comprise a two dimensional array of sensing elements. Each sensing element may be referred to as a pixel of the radiation detector. It will be appreciated that the plurality of positions on the radiation detector at which the phase of a harmonic of the oscillating signal is determined may each correspond to different sensing element or pixel of the radiation detector.

In some embodiments, each of the first and second portions of the object plane patterning devices may comprise a one-dimensional diffraction grating with a 50% duty cycle. With such a first patterning device, the efficiencies of the even diffraction orders (except the 0^{th} diffraction order) are zero. Therefore, the only two pairs of first diffraction beams that differ in order by ±1 (and therefore contribute to the first harmonic of such an oscillating phase-scanning signal) are the 0^{th} order beam with either the ±1^{st} order beams. Furthermore, with this geometry for the first patterned region, the scattering efficiencies are symmetric such that the efficiencies of the ±1^{st} order diffraction beams are both the same.

A new method 60 of determining a physical quantity using a sensor system configured to sample a plurality of positions is now described with reference to FIG. 6. Sampling at each position uses an object plane patterning device 51-57 and an image plane sensor. In an embodiment, the method determines aberrations of a projection system PS. The method 60 may use a corresponding plurality of image plane sensors for the plurality of object plane patterning devices 51-57.

The method 60 comprises four scanning measurements 61, 62, 63, 64, each which may be continuous or stepped (stepwise), and may comprise a shearing interferometry process. Although shown in a particular order in the schematic illustration of FIG. 6, it will be appreciated that the four measurements 61, 62, 63, 64 may be performed in any order. The four measurements 61, 62, 63, 64 are now described.

A first measurement 61 comprises positioning the plurality of object plane patterning devices 51-57 and one or more image plane sensors such that the incident radiation, which may be from projection system PS, is arranged to form an image of the first portion 51a-57a of each of the plurality of object plane patterning devices 51-57 on a corresponding location on a patterning device of the one or more image plane sensors. Then the first measurement 61 is performed. The first measurement may be a first continuous scanning measurement, or may be a first stepwise measurement. The first measurement may be a first shearing interferometry process. The first measurement 61 comprises scanning at least one of the plurality of object plane patterning devices 51-57 or a corresponding plurality of image plane sensors through a plurality of positions separated in a first direction so as to generate a first data set S₁, which may be a first phase-scanning data set. The first direction at S1 may be the y direction. It is to be noted that this is merely an exemplary direction, and it will be appreciated that any direction may be used. The first direction may comprise a component parallel to the directional orientation of the grating of the first portion of the object plane patterning device (e.g. where the first portion of the object plane patterning device has a first shearing direction (u), and the first direction is the y direction) and a component parallel to the directional orientation of the grating of the second portion of the grating of the second portion of the object plane patterning device (e.g. where the second portion of the object plane patterning device has a second shearing direction (v), and the first direction is the y direction).

A second measurement 62 comprises positioning the plurality of object plane patterning devices 51-57 and at least one image plane sensor such that the incident radiation is arranged to form an image of the first portion 51a-57a of each of the plurality of object plane patterning devices 51-57 on a patterning device of the at least one image plane sensor, which may be a different one of a plurality of image plane sensors. Then the second measurement 62 is performed. The second measurement 62 may be a second continuous scanning measurement, or may be a second stepwise measurement. The second measurement may be a second shearing interferometry process and comprise scanning at least one of the plurality of object plane patterning devices 51-57 or a corresponding plurality of image plane sensors through a plurality of positions separated in a second direction (e.g. x) so as to generate a second data set S₂, which may be a second phase-scanning data set. The second direction (e.g. x) is different to the first direction (e.g. y). The second direction may comprise a component parallel to the directional orientation of the grating of the first portion of the object plane patterning device, e.g. where the first portion of the object plane patterning device has a first shearing direction (u), and a component parallel to the directional orientation of the grating of the second portion of the object plane patterning device, e.g. where the second portion of the object plane patterning device has a second shearing direction (v).

A third stepping measurement 63 comprises positioning the plurality of object plane patterning devices 51-57 and at least one image plane sensor such that the incident radiation is arranged to form an image of the second portion 51b-57b of each of the plurality of object plane patterning devices 51-57 on a patterning device of an image plane sensor, wherein the image plane sensor may be a plurality of corresponding image plane sensors. Then the third measurement 63, which may be a third continuous scanning measurement, or may be a third stepwise measurement. The third measurement may be a shearing interferometry process. The third measurement 63 comprises scanning at least one of the plurality of object plane patterning devices 51-57 or corresponding plurality of image plane sensors through a plurality of positions separated in the first direction (e.g. y) so as to generate a third data set S₃, which may be a third phase-scanning data set.

A fourth measurement 64 comprises positioning the plurality of object plane patterning devices 51-57 and at least one image plane sensor such that the incident radiation is arranged to form an image of the second portion 51b-57b of each of the plurality of object plane patterning devices 51-57 on a patterning device of an image plane sensor. Then the fourth measurement 64 is performed. The fourth measurement may be a fourth continuous scanning measurement, or may be a fourth stepwise measurement. The fourth measurement may be a shearing interferometry process. The fourth measurement 64 comprises scanning at least one of the plurality of object plane patterning devices 51-57 or corresponding plurality of image plane sensors through a plurality of positions separated in the second direction (e.g. x) so as to generate a fourth data set S₄, which may be a fourth phase-scanning data set.

The new method 60 further comprises a step 65 of combining the first, second, third and fourth data sets S₁, S₂, S₃, S₄ so as to determine the physical quantity, which may be for example one or more aberrations of the projection system PS. The physical quantity may alternatively be an intensity relating to e.g. the alignment of a substrate.

One of the first and second directions (e.g. y, x) may be such that a sign of its component parallel to the first orientation, which may e.g. be a first shearing direction (u), is opposite to a sign of its component parallel to the second orientation, which may e.g. be a shearing direction (v), and the other one of the first and second directions (e.g. y, x) may be such that a sign of its component parallel to the first orientation, which may be a first shearing direction (u), is the same as a sign of its component parallel to the second orientation, which may be a second shearing direction (v). It will be appreciated however, that different positions may have different orientations, and thus different shearing directions.

One example of the configuration of the first and second directions (e.g. x, y) and the first and second orientations (e.g. shearing directions u, v) is shown in FIG. 5. The first direction (y) has a positive component parallel to the first shearing direction (u) and a positive component parallel to the second shearing direction (v). The second direction (x) has a positive component parallel to the first shearing direction (u) and a negative component parallel to the second shearing direction (v). In the example shown in FIG. 5, the first shearing direction (u) and the second shearing direction (v) are mutually orthogonal; the first direction (y) and the second direction (x) are mutually orthogonal; and the first direction (y) and the second direction (x) are each aligned at 45° relative to each of the first shearing direction (u) and the second shearing direction (v). It will be appreciated that the grating orientations are not limited to shearing directions (u, v), and first and second stepping directions are not limited to x and y directions.

The method 60 shown schematically in FIG. 6 is advantageous as it results in the determined physical quantity, which may be one or more aberrations of the projection system PS or may be an intensity relating to an alignment measurement, being less sensitive to noise contributions, as now discussed.

It will be appreciated that each of the first, second, third and fourth data sets S₁, S₂, S₃, S₄ is generated using radiation B and that the radiation may be subject to intensity noise (i.e. the intensity of the radiation B will be subject to variations or fluctuations over time). The data generated within any one of the first, second, third and fourth data sets S₁, S₂, S₃, S₄ is formed with the same emission, e.g. same pulses, of radiation and, therefore, there will be a correlation in the intensity noise errors within any one of the first, second, third and fourth data sets S₁, S₂, S₃, S₄.

Where each of the first and second directions (e.g. y, x) comprises a component parallel to the first orientation (e.g. shearing direction u) and a component parallel to the second orientation (e.g. shearing direction v), scanning in either of the first and second directions effectively results in scanning in both the first and second orientations (e.g. u, v) simultaneously. Therefore, although the plurality of object plane patterning devices 51-57 comprises a first set of patterning devices 51, 53, 54, 55, 57 and a second set of patterning devices 52, 56, during generation of any one of the four data sets S₁, S₂, S₃, S₄ scanning in either the first or second direction (e.g. y, x) will result in scanning in the orientation direction of all of the portions of the object plane patterning devices 51-57 being exposed at any given time and therefore will result in phase-scanning data being recorded by the detector 23.

FIG. 7 shows an example set of phase-scanning measurements taken (which may be representative of data recorded during any of the four phase-scanning processes 61, 62, 63, 64). What is shown in FIG. 7 is a single phase-scanning curve for each of the four object plane patterning devices 51-57. It will be appreciated that each of the seven curves shown in FIG. 7 may represent a single pixel (which may relate to a single position, e.g. in the pupil plane where the radiation is from a projection system PS) from a portion of the detector corresponding to a different one of the image plane sensors. The phases of the curves for the corresponding plurality of pixels on the one or more image plane sensors may be used to generate a map that represents the gradient of the aberration (relative phase) map in the shearing direction of the object plane grating currently being illuminated.

Each of the seven curves shown in FIG. 7 comprises five data points to which a sine curve has been fitted. It will be appreciated that the five data points, which correspond to five phase steps, is merely an example. The number of phase steps and resulting data points to which a sine or cosine is fit may be any number of three or more. Any intensity variations that occur during the generation of the seven curves shown in FIG. 7 (and the other pixels, corresponding to other positions in e.g. the pupil plane) will, in general, affect the position of the data points in the seven curves. In turn, this will affect the fitted sine curve and therefore the extracted phase of the sine curve (which relates to a difference in the relative phases of two points from different positions in e.g. the pupil plane, separated in e.g. the shearing direction). For example, as indicated by arrows an upward fluctuation of the intensity of the radiation during the capture of the second data point will move all of the second data points up. In turn, this will affect the sine curve fitted to the data and therefore the phase extracted from the fitted sine curve. Note that such intensity variations will affect all of the seven curves, i.e. the intensity fluctuations from the seven curves are all correlated.

The phase-scanning data typically is related to the differential of the aberration (relative wavefront) map in the direction of the shearing direction (either u or v) of the portion of the object plane patterning device being illuminated with radiation (i.e. either the first portion 51a-57a or the second portion 51b-57b). Therefore, the intensity noise errors of data from the data sets S₁, S₂, S₃, S₄ will typically result in an error in the differential of the wavefront map in the direction of the shearing direction of the portion of the object plane patterning device being illuminated with radiation.

Since the first portion of the first set of patterning devices 51, 53, 54, 55, 57 has the first shearing direction (u); and the first portion of the second set of patterning devices 52, 56 has the second shearing direction (v), when the first portion of the first set of patterning devices 51, 53, 54, 55, 57 is being illuminated, the first set of patterning devices will have an error (from the intensity noise) in the differential of the wavefront map in the direction of the first shearing direction (u) and the second set of patterning devices 52, 56 will have a correlated error in the differential of the wavefront map in the direction of the second shearing direction (v).

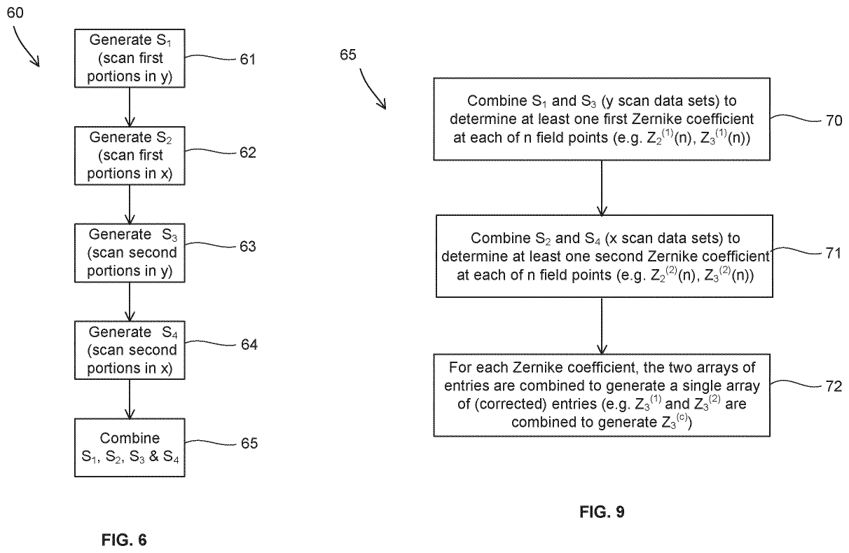

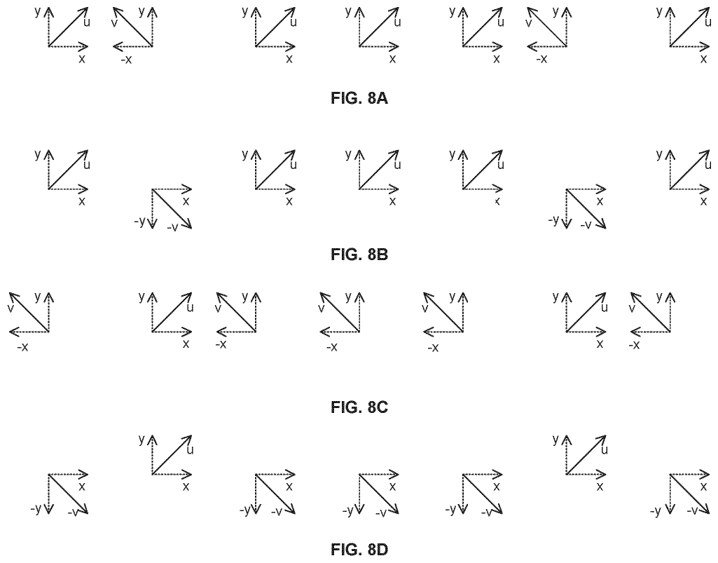

An error in the differential of the wavefront map in the direction of the first or second shearing directions (u, v) results in an error in the differential of the wavefront map in both the first and second directions (x, y). The sign(s) of the errors in the differential of the wavefront map in the first and second directions (x, y) are dependent on both the sign of the error in the differential of the wavefront map in the direction of the first or second shearing directions (u, v) and also the signs of the components of the first and second directions (x, y) parallel to the first and second shearing directions (u, v), as described below with reference to FIGS. 8A to 8D.

Since one of the first and second directions (y, x) is such that a sign of its component parallel to the first shearing direction (u) is opposite to a sign of its component parallel to the second shearing direction (v) and the other one of the first and second directions (y, x) is such that a sign of its component parallel to the first shearing direction (u) is the same as a sign of its component parallel to the second shearing direction (v), when scanning in one direction (y, x), it can be ensured that the sign of the errors in the differential of the wavefront map in the other direction (y, x) is different for each of the first and second sets. In other words, the correlated intensity errors will have a higher order fingerprint. In turn, this allows such intensity errors to be modelled away. This is now described with reference to FIGS. 8A to 8D.

FIG. 8A shows the intensity error for each of the seven field points due to an intensity fluctuation (solid arrow) and the components of this intensity error in each of the two directions (dotted arrows) for the first measurement, which in this case is a first shearing interferometry process 61.

FIG. 8B shows the intensity error for each of the seven field points due to an intensity fluctuation (solid arrow) and the components of this intensity error in each of the two directions (dotted arrows) for the second measurement, in this case a second shearing interferometry process 62.

FIG. 8C shows the intensity error for each of the seven field points due to an intensity fluctuation (solid arrow) and the components of this intensity error in each of the two directions (dotted arrows) for the third measurement, in this case a third shearing interferometry process 63.

FIG. 8D shows the intensity error for each of the seven field points due to an intensity fluctuation (solid arrow) and the components of this intensity error in each of the two directions (dotted arrows) for the fourth measurement, in this case a fourth shearing interferometry process 64.

Each Zernike coefficient may be obtained from data obtained in two directions fitted at the same time. During the first shearing interferometry process 61, the phase scanning direction is the positive y-direction. Since the positive y-direction has a component in the positive u-direction and the positive v-direction, this is equivalent to scanning in the positive u-direction and the positive v-direction. Therefore, as shown in FIG. 8A, the intensity error will be in the positive u-direction for the first set of patterning devices 51, 53, 54, 55, 57 (recall that in the shearing interferometry process 61 the first portion of the object plane patterning devices 51-57 is illuminated). Similarly, the intensity error will be in the positive v-direction for the second set of patterning devices 52, 56. As also shown in FIG. 8A, the positive u-direction has a component in the positive y-direction and the positive x-direction and the positive v-direction has a component in the positive y-direction and the negative x-direction. Therefore, the intensity errors or fluctuations during the first shearing interferometry process 61 will result in an error in the gradient (or tilt) of the reconstructed wavefront map in the y-direction (which is the third Zernike coefficient Z₃) which has the same sign for all of the object plane patterning devices 51-57 (i.e. this will result in an offset in the positive y-direction). Furthermore, the intensity errors or fluctuations during the first shearing interferometry process 61 will result in an error in the gradient (or tilt) of the reconstructed wavefront map in the x-direction (which is the second Zernike coefficient Z₂) which has one sign for the first set of patterning devices 51, 53, 54, 55, 57 and an opposite sign for the second set of patterning devices 52, 56.

During the second shearing interferometry process 62, the phase scanning direction is the positive x-direction. Since the positive x-direction has a component in the positive u-direction and the negative v-direction, this is equivalent to scanning in the positive u-direction and the negative v-direction. Therefore, as shown in FIG. 8B, the intensity error will be in the positive u-direction for the first set of patterning devices 51, 53, 54, 55, 57 (recall that in the shearing interferometry process 61 the first portion of the object plane patterning devices 51-57 is illuminated). Similarly, the intensity error will be in the negative v-direction for the second set of patterning devices 52, 56. As also shown in FIG. 8B, the positive u-direction has a component in the positive y-direction and the positive x-direction and the negative v-direction has a component in the negative y-direction and the positive x-direction. Therefore, the intensity errors or fluctuations during the second shearing interferometry process 62 will result in an error in the gradient (or tilt) of the reconstructed wavefront map in the x-direction (which is the second Zernike coefficient Z₂) which has the same sign for all of the object plane patterning devices 51-57 (i.e. this will result in an offset in the positive x-direction). Furthermore, the intensity errors or fluctuations during the first shearing interferometry process 61 will result in an error in the gradient (or tilt) of the reconstructed wavefront map in the y-direction (which is the third Zernike coefficient Z₃) which has one sign for the first set of patterning devices 51, 53, 54, 55, 57 and an opposite sign for the second set of patterning devices 52, 56.

During the third shearing interferometry process 63, the phase scanning direction is the positive y-direction. Since the positive y-direction has a component in the positive u-direction and the positive v-direction, this is equivalent to scanning in the positive u-direction and the positive v-direction. Therefore, as shown in FIG. 8C, the intensity error will be in the positive v-direction for the first set of patterning devices 51, 53, 54, 55, 57 (recall that in the shearing interferometry process 61 the second portion of the object plane patterning devices 51-57 is illuminated). Similarly, the intensity error will be in the positive u-direction for the second set of patterning devices 52, 56. As also shown in FIG. 8C, the positive u-direction has a component in the positive y-direction and the positive x-direction and the positive v-direction has a component in the positive y-direction and the negative x-direction. Therefore, the intensity errors or fluctuations during the third shearing interferometry process 63 will result in an error in the gradient (or tilt) of the reconstructed wavefront map in the y-direction (which is the third Zernike coefficient Z₃) which has the same sign for all of the object plane patterning devices 51-57 (i.e. this will result in an offset in the positive y-direction). Furthermore, the intensity errors or fluctuations during the third shearing interferometry process 63 will result in an error in the gradient (or tilt) of the reconstructed wavefront map in the x-direction (which is the second Zernike coefficient Z₂) which has one sign for the first set of patterning devices 51, 53, 54, 55, 57 and an opposite sign for the second set of patterning devices 52, 56.

During the fourth shearing interferometry process 64, the phase scanning direction is the positive x-direction. Since the positive x-direction has a component in the positive u-direction and the negative v-direction, this is equivalent to scanning in the positive u-direction and the negative v-direction. Therefore, as shown in FIG. 8D, the intensity error will be in the negative v-direction for the first set of patterning devices 51, 53, 54, 55, 57 (recall that in the shearing interferometry process 61 the first portion of the object plane patterning devices 51-57 is illuminated). Similarly, the intensity error will be in the positive u-direction for the second set of patterning devices 52, 56.

As also shown in FIG. 8D, the positive u-direction has a component in the positive y-direction and the positive x-direction and the negative v-direction has a component in the negative y-direction and the positive x-direction. Therefore, the intensity errors or fluctuations during the second shearing interferometry process 62 will result in an error in the gradient (or tilt) of the reconstructed wavefront map in the x-direction (which is the second Zernike coefficient Z₂) which has the same sign for all of the object plane patterning devices 51-57 (i.e. this will result in an offset in the positive x-direction). Furthermore, the intensity errors or fluctuations during the first shearing interferometry process 61 will result in an error in the gradient (or tilt) of the reconstructed wavefront map in the y-direction (which is the third Zernike coefficient Z₃) which has one sign for the first set of patterning devices 51, 53, 54, 55, 57 and an opposite sign for the second set of patterning devices 52, 56.

The inventors have realized that if the intensity noise errors are merely an offset then it would be impossible to determine and correct for this error without an independent measurement of the offset. In contrast, when the intensity error has a higher order fingerprint (i.e. the error for some field points has an opposite sign to the error for the other field points) these (correlated) intensity errors can be modelled away.

Ways in which the correlated intensity errors can be modelled away in step 65 of combining the first, second, third and fourth data sets S₁, S₂, S₃, S₄ so as to determine the physical quantity, which may be one or more aberrations of the projection system PS, are now discussed with reference to FIG. 9.

In the example shown in FIG. 9, step 65 comprises the following steps.

In one step 70, the first data set S₁ and the third data set S₃ are combined. In particular, the first data set S₁ and the third data set S₃ may be combined so as to determine, for each of the seven pairs of object plane patterning devices 51-57 and image plane sensors (i.e. for each of the seven field points) at least one Zernike coefficient. For example, the first data set S₁ and the third data set S₃ may be combined so as to determine, for each of the e.g. seven pairs of object plane patterning devices 51-57 and image plane sensors (i.e. for each of the seven field points): a first wavefront tilt coefficient

$${Z}_{3}^{( 1 )}$$

in the first direction (y); and a first wavefront tilt coefficient

$${Z}_{2}^{( 1 )}$$

in the second direction (x). This may, for example, involve reconstructing a first wavefront map W⁽¹⁾(x,y) from the first phase-scanning data set S₁ and the third phase-scanning data set S₃ for each of the seven pairs of object plane patterning devices 51-57 and image plane sensors (see equation (1)).

In another step 71, the second data set S₂ and the fourth data set S₄ are combined. In particular, the second data set S₂ and the fourth data set S₄ may be combined so as to determine, for each of the e.g. seven pairs of object plane patterning devices 51-57 and image plane sensors (i.e. for each of the exemplary seven field points) at least one Zernike coefficient. For example, the second data set S₂ and the fourth data set S₄ may be combined so as to determine, for each of the seven pairs of object plane patterning devices 51-57 and image plane sensors (i.e. for each of the seven field points): a second wavefront tilt coefficient

$${Z}_{3}^{( 2 )}$$

in the first direction (y); and a first wavefront tilt coefficient

$${Z}_{2}^{( 2 )}$$

in the second direction (x). This may, for example, involve reconstructing a second wavefront map W⁽²⁾(x,y) from the second phase-stepping data set S₂ and the fourth phase-scanning data set S₄ for each of the seven pairs of object plane patterning devices 51-57 and image plane sensors (see equation (1)).

Following steps 70 and 71, for each pair of object plane patterning devices 51-57 and image plane sensors, or field points, there will be two values for each Zernike coefficient. This redundancy is used to model away the intensity noise errors so as to generate one corrected value for each Zernike coefficient for each field point, as now discussed.

Following steps 70 and 71, if there are n pairs of object plane patterning devices 51-57 and image plane sensors, or field points, (for example may n be seven) then, for each Zernike coefficient, the method will have generated two arrays of numbers, each array having n entries. For example, if both tilt Zernike coefficients have been generated, there will be four arrays of n entries: a first wavefront tilt coefficient

$${Z}_{3}^{( 1 )} ( n )$$

in the first direction (y); a second wavefront tilt coefficient

$${Z}_{3}^{( 2 )} ( n )$$

in the first direction (y); a first wavefront tilt coefficient

$${Z}_{2}^{( 1 )} ( n )$$

in the second direction (x); and a second wavefront tilt coefficient

$${Z}_{2}^{( 2 )} ( n )$$

in the second direction (x). The intensity noise errors within each array are correlated.

At a next step 72, for each Zernike coefficient, the two arrays of n entries are combined to generate a single array of n (corrected) entries. For example, the first wavefront tilt coefficient

$${Z}_{3}^{( 1 )} ( n )$$

in the first direction (e.g. y) is combined with the second wavefront tilt coefficient

$${Z}_{3}^{( 2 )} ( n )$$

in the second direction (e.g. x) to generate a corrected wavefront tilt coefficient

$${Z}_{3}^{( c )} ( n ) .$$

In particular, this combination is made, using the correlation of the intensity noise contributions in each array so as to at least partially correct for errors caused by intensity variations in the radiation used to generate the first data set S₁ and the third data set S₃.

Similarly, the first wavefront tilt coefficient

$${Z}_{2}^{( 1 )} ( n )$$

in the second direction (e.g. x) and the second wavefront tilt coefficient

$${Z}_{2}^{( 2 )} ( n )$$

in the first direction (e.g. y) are combined to generate a corrected wavefront tilt coefficient

$${Z}_{2}^{( c )} ( n ) .$$

In particular, this combination is made, using the correlation of the intensity noise contributions in each array so as to at least partially correct for errors caused by intensity variations in the radiation used to generate the second data set S₂ and the fourth data set S₄.

In particular, the combinations made in step 72 may be made as follows.

For example, combining the first wavefront tilt coefficient

$${Z}_{3}^{( 1 )} ( n )$$

in the first direction (e.g. y) with the second wavefront tilt coefficient

$${Z}_{3}^{( 2 )} ( n )$$

in the second direction (e.g. x) to generate a corrected wavefront tilt coefficient

$${Z}_{3}^{( c )} ( n )$$

may comprise performing a least squares fit to simultaneously minimise:

$${\sum }_{i = 1}^{n} {( {Z}_{3}^{( 1 )} ( i ) - {Z}_{3}^{( c )} ( i ) + {c}_{1} \cdot I ( i ) )}^{2} \qquad ( 5 )$$

$$and$$

$${\sum }_{i = 1}^{n} {( {Z}_{3}^{( 2 )} ( i ) - {Z}_{3}^{( c )} ( i ) + {c}_{2} \cdot V ( i ) )}^{2} \qquad ( 6 )$$

where c₁ and c₂ are two constants (parameters of the fit), I(i) is an identity array such that I(i)=1 for all i, and V(i) is an array having entries of either +1 or −1, where V(i)=1 for entries corresponding to the first set of object plane patterning devices 51, 53, 54, 55, 57 and V(i)=−1 for entries corresponding to the second set of object plane patterning devices 52, 56. Therefore, for the example arrangement of object plane patterning devices 51-57 shown in FIG. 5, V=(1,−1,1,1,1,−1,1). That is, the array V(i) models the intensity error with a higher order fingerprint (which in this case came from the data that used the x-direction).

Similarly, combining the first wavefront tilt coefficient in the second coefficient

$${Z}_{2}^{( 1 )} ( n )$$

in the second direction (e.g. x) with the second wavefront tilt coefficient

$${Z}_{2}^{( 2 )} ( n )$$

in the first direction (e.g. y) to generate a corrected wavefront tilt coefficient

$${Z}_{2}^{( c )} ( n )$$

may comprise performing a least squares fit to simultaneously minimise:

$${\sum }_{i = 1}^{n} {( {Z}_{2}^{( 2 )} ( i ) - {Z}_{2}^{( c )} ( i ) + {c}_{3} \cdot I ( i ) )}^{2} \qquad ( 7 )$$

$$and$$

$${\sum }_{i = 1}^{n} {( {Z}_{2}^{( 1 )} ( i ) - {Z}_{2}^{( c )} ( i ) + {c}_{4} \cdot V ( i ) )}^{2} \qquad ( 8 )$$

where c₃ and c₄ are two constants (parameters of the fit). The array V(i) models the intensity error with a higher order fingerprint (which in this case came from the data that used the y-direction).

Some embodiments of the present disclosure relate to a computer readable medium carrying a computer program comprising computer readable instructions configured to cause a computer to carry out the method 60 described above with reference to FIGS. 5 to 9.

Some embodiments of the present disclosure relate to a computer apparatus comprising: a memory storing processor readable instructions, and a processor arranged to read and execute instructions stored in said memory, wherein said processor readable instructions comprise instructions arranged to control the computer to carry out the method 60 described above with reference to FIGS. 5 to 9.

Some embodiments of the present disclosure relate to a measurement system for determining a physical quantity, the measurement system comprising: a controller configured to carry out the method 60 described above with reference to FIGS. 5 to 9. The apparatus may comprise, or form part of, a lithographic apparatus LA. Alternatively, the apparatus may comprise, or form part of, a metrology tool.

Although the above described embodiments use the first harmonic of the phase scanning signal it will be appreciated that in alternative embodiments higher harmonics of the phase scanning signal may alternatively be used.

Although the above described embodiments use a first patterned region 31 comprising a one-dimensional diffraction grating 31 with a 50% duty cycle it will be appreciated that in alternative embodiments other the first patterned region 31 may use different geometries. For example, in some embodiments, the first patterned region 31 may comprise a two-dimensional checkerboard diffraction grating with a 50% duty cycle.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below. Other aspects of the invention are set-out as in the following numbered clauses.
1. A method of determining a physical quantity, the method using a sensor system configured to sample a plurality of positions, wherein sampling at each position uses an object plane patterning device and an image plane sensor,
   wherein each object plane patterning device comprises a first portion and a second portion, the first portion being different to the second portion, and wherein the first and second portions of at least one of the object plane patterning devices are transposed relative to the first and second portions of the other object plane patterning devices; and
   wherein the method comprises:
      using the first portion of each object plane patterning device and performing a first measurement in a first direction so as to generate a first data set;
      using the second portion of each object plane patterning device and performing a second measurement in the first direction so as to generate a second data set;
      using the first portion of each object plane patterning device and performing a third measurement in a second direction so as to generate a third data set, the second direction being different to the first direction;
      using the second portion of each object plane patterning device and performing a fourth measurement in the second direction so as to generate a fourth data set; and
      combining the first, second, third and fourth data sets so as to determine the physical quantity.
2. The method of clause 1 wherein radiation having a common noise source is incident on each object plane patterning device and the image plane sensor to generate the first, second, third and/or fourth data sets.
3. The method of any preceding clause wherein the object plane patterning device comprises a grating.
4. The method of any preceding clause wherein the orientation of the first portion of the object plane patterning device is orthogonal to the orientation of the second portion.
5. The method of any preceding clause wherein the first orientation of the at least one object plane patterning device is orthogonal to the second orientation of the other object plane patterning devices.
6. The method of any preceding clause wherein the first, second, third and fourth measurements form part of a shearing interferometry process.
7. The method of any preceding clause wherein the first portion has a first shearing direction and the second portion has a second shearing direction, the second shearing direction being different from the first shearing direction.
8. The method of clause 7 wherein the first direction comprises a component parallel to the first shearing direction and a component parallel to the second shearing direction;
and wherein the second direction comprises a component parallel to the first shearing direction and a component parallel to the second shearing direction.
9. The method of clause 8 wherein one of the first and second directions is such that a sign of its component parallel to the first shearing direction is opposite to a sign of its component parallel to the second shearing direction and the other one of the first and second directions is such that a sign of its component parallel to the first shearing direction is the same as a sign of its component parallel to the second shearing direction.
10. The method of any preceding clause wherein the image sensor comprises a plurality of image sensors.
11. The method of any preceding clause wherein the image plane sensor comprises a second patterning device positionable so as to receive radiation from the plurality of object plane patterning devices; and
a detector arranged to receive radiation from the second patterning device.
12. The method of clause 10 wherein each of the plurality of image plane sensors comprises a second patterning device positionable so as to receive radiation from a corresponding one of the plurality of object plane patterning devices; and
   wherein the plurality of image plane sensors comprises a detector arranged to receive radiation from the plurality of second patterning devices.
13. The method of any preceding clause wherein combining the first, second, third and fourth data sets so as to determine the physical quantity comprises:
   combining the first data set and the second data set so as to determine for each sampled position at least one first physical parameter;
   combining the third data set and the fourth data set so as to determine for each sampled position at least one second physical parameter; and
   combining the determined first physical parameter for each sampled position and the determined second physical parameter for each sampled position to form an output corrected physical parameter for each sampled position so as to at least partially correct for errors in the determined first and second physical parameters caused by intensity variations in the radiation used to generate the first, second, third and/or fourth data sets.
14. The method of any preceding clause wherein the physical quantity comprises one or more aberrations of a projection system.
15. The method of clause 13 wherein the physical quantity comprises one or more aberrations of a projection system, and the first, second, third and fourth physical parameters respectively correspond to first, second, third and fourth aberration coefficients.
16. The method of clause 15 wherein the step of
   combining the first data set and the second data set so as to determine one or more aberrations further comprises: determining a first wavefront tilt coefficient in the first direction; and the step of
   combining the second data set and the fourth data set so as to determine one or more aberrations further comprises: determining a second wavefront tilt coefficient in the first direction; and
   combining the determined first wavefront tilt coefficients in the first direction for each sampled position and the determined second wavefront tilt coefficients in the first direction for each sampled position so as to form an output wavefront tilt coefficient in the first direction for each sampled position so as to at least partially correct for errors in the determined first wavefront tilt coefficients in the first direction and the determined second wavefront tilt coefficients in the first direction caused by intensity variations in the radiation used to generate the first data set and the second data set.
17. The method of clause 16 wherein combining the determined first wavefront tilt coefficients in the first direction for each sampling position and the determined second wavefront tilt coefficients in the first direction for each sampling position so as to form an output wavefront tilt coefficient in the first direction for each sampling position comprises:
   performing a least squares fit so as to simultaneously minimise:
      the root mean square for each sampling position of the difference between: (a) the determined first wavefront tilt coefficients in the first direction; and (b) the output wavefront tilt coefficient in the first direction plus a first constant; and
      the root mean square for each sampling position of the difference between: (a) the determined second wavefront tilt coefficients in the first direction; and (b) the output wavefront tilt coefficient in the first direction plus a second constant multiplied by ±1 for the first portions of the grating of the object plane patterning devices and multiplied by −1 for the second portions of the grating of the object plane patterning devices.
18. The method of any of clauses 1-13 wherein the physical quantity comprises an intensity.
19. The method of any of clauses 1-13 wherein the physical quantity comprises one or more intensities of a measured radiation, and the first, second, third and fourth physical parameters respectively correspond to first, second, third and fourth intensity values.
20. The method of any preceding clause wherein combining the first, second, third and fourth data sets so as to determine the physical quantity comprises:
   combining the first data set and the second data set so as to, for each sampling position, determine a first wavefront tilt coefficient in the second direction;
   combining the third data set and the fourth data set so as to, for each sampling position, determine a second wavefront tilt coefficient in the second direction; and
   combining the determined first wavefront tilt coefficients in the second direction for each sampling position and the determined second wavefront tilt coefficients in the second direction for each sampling position so as to form an output wavefront tilt coefficient in the second direction for each sampling position so as to at least partially correct for errors in the determined first wavefront tilt coefficients in the second direction and the determined second wavefront tilt coefficients in the second direction caused by intensity variations in the radiation used to generate the second data set and the fourth data set.
21. The method of clause 20 wherein combining the determined first wavefront tilt coefficients in the second direction for each sampling position and the determined second wavefront tilt coefficients in the second direction for each sampling position so as to form an output wavefront tilt coefficient in the second direction for each sampling position comprises:
   performing a least squares fit so as to simultaneously minimise:
      the root mean square for the plurality sampling positions of the difference between: (a) the determined first wavefront tilt coefficients in the second direction; and (b) the output wavefront tilt coefficient in the second direction plus a third constant; and
      the root mean square for the plurality of sampling positions of the difference between: (a) the determined second wavefront tilt coefficients in the second direction; and (b) the output wavefront tilt coefficient in the second direction plus a fourth constant multiplied by ±1 for the first portions of the gratings of the object plane patterning devices and multiplied by −1 for the second portions of the gratings of the object plane patterning devices.
22. The method of any preceding clause wherein the first direction and the second direction are each aligned at 45° relative to each of the first shearing direction and the second shearing direction.
23. The method of any preceding clause wherein each measurement comprises:
   illuminating the plurality of object plane patterning devices with first radiation;
   forming, an image of each of the plurality of object plane patterning devices on a patterning device of a different one of the plurality of image plane sensors;
   scanning at least one of the plurality of object plane patterning devices or the corresponding plurality of image plane sensors through a plurality of positions separated in a direction so as to generate an oscillating phase-scanning signal for each of the plurality of sampling positions; and
   determining a phase of a harmonic of the oscillating signal at a plurality of positions on a radiation detector.
24. The method of clause 23 wherein the harmonic of the oscillating signal, which is equated to a difference in the aberration map between a pair of positions in a pupil plane of a projection system at each of the plurality of positions on the radiation detector, is a first harmonic.
25. The method of clause 24 wherein the pair of positions in the pupil plane of the projection system are separated in a shearing direction by a shearing distance which corresponds to twice the distance in the pupil plane between two adjacent first diffraction beams.
26. A computer readable medium carrying a computer program comprising computer readable instructions configured to cause a computer to carry out a method according to any one of clauses 1 to 25.
27. A computer apparatus comprising:
   a memory storing processor readable instructions, and
   a processor arranged to read and execute instructions stored in said memory, wherein said processor readable instructions comprise instructions arranged to control the computer to carry out the method according to any one of clauses 1 to 25.
28. A measurement system for determining a physical quantity, the measurement system comprising:
   a plurality of object plane patterning devices comprising: a first set of patterning devices having a first orientation; and a second set of patterning devices having a second orientation, the second orientation being different to the first orientation;
   an illumination system arranged to illuminate the plurality of object plane patterning devices with radiation so as to form a plurality of first diffraction beams, the first diffraction beams from each of the first set of patterning devices being separated in a modulation direction corresponding to the first orientation of the gratings and the first diffraction beams from each of the second set of patterning devices being separated in a modulation direction corresponding to the second orientation of the gratings;
   an image plane sensor comprising a patterning device and a radiation detector;
   the illumination system being configured to form an image of each of the plurality of object plane patterning devices on the patterning device of the image plane sensor so as to form a plurality of second diffraction beams from each of the first diffraction beams;
   a positioning apparatus configured to move the plurality of object plane patterning devices in a first direction or a second direction; and
   a controller configured to carry out the method of any one of clauses 1 to 25.
29. A measurement system for determining a physical quantity, the measurement system comprising:
   a plurality of object plane patterning devices comprising: a first set of patterning devices having a first orientation; and a second set of patterning devices having a second orientation, the second orientation being different to the first orientation;
   an illumination system arranged to illuminate the plurality of object plane patterning devices with radiation so as to form a plurality of first diffraction beams, the first diffraction beams from each of the first set of patterning devices being separated in a modulation direction corresponding to the first orientation and the first diffraction beams from each of the second set of patterning devices being separated in a modulation direction corresponding to the second orientation;
   a plurality of image plane sensors, each comprising a patterning device and each in communication with a radiation detector;
   the illumination system being configured to form an image of each of the plurality of object plane patterning devices on the patterning device of the image plane sensor so as to form a plurality of second diffraction beams from each of the first diffraction beams;
   a positioning apparatus configured to move at least one of the plurality of object plane patterning devices or the corresponding plurality of image plane sensors in a first direction or a second direction; and
   a controller configured to carry out the method of any one of clauses 1 to 25.
30. A lithographic apparatus comprising the measurement system of clause 28 or 29.
31. A metrology tool comprising the measurement system of clause 28 or 29.

1.-31. (canceled)

32. A method of determining a physical quantity, the method using a sensor system configured to sample a plurality of positions, wherein sampling at each position uses an object plane patterning device and an image plane sensor, wherein each object plane patterning device comprises a first portion and a second portion, the first portion being different to the second portion, and wherein the first and second portions of at least one of the object plane patterning devices are transposed relative to the first and second portions of the other object plane patterning devices, the method comprising:
using the first portion of each object plane patterning device and performing a first measurement in a first direction so as to generate a first data set;
using the second portion of each object plane patterning device and performing a second measurement in the first direction so as to generate a second data set;
using the first portion of each object plane patterning device and performing a third measurement in a second direction so as to generate a third data set, the second direction being different to the first direction;
using the second portion of each object plane patterning device and performing a fourth measurement in the second direction so as to generate a fourth data set; and
combining the first, second, third and fourth data sets so as to determine the physical quantity.

33. The method of claim 32, wherein radiation having a common noise source is incident on each object plane patterning device and the image plane sensor to generate the first, second, third and/or fourth data sets.

34. The method of claim 32, further comprising providing the object plane patterning device comprising a grating.

35. The method of claim 32, wherein the orientation of the first portion of the object plane patterning device is orthogonal to the orientation of the second portion.

36. The method of claim 32, wherein the first orientation of the at least one object plane patterning device is orthogonal to the second orientation of the other object plane patterning devices.

37. The method of claim 32, wherein the first, second, third and fourth measurements form part of a shearing interferometry process.

38. The method of claim 32, wherein the first portion has a first shearing direction and the second portion has a second shearing direction, the second shearing direction being different from the first shearing direction.

39. The method of claim 32, further comprising providing the image plane sensor comprising a plurality of image plane sensors.

40. The method of claim 32, further comprising providing the image plane sensor comprising a second patterning device positionable so as to receive radiation from the plurality of object plane patterning devices; and
arranging a detector to receive radiation from the second patterning device.

41. The method of claim 32, wherein combining the first, second, third and fourth data sets so as to determine the physical quantity comprises:
combining the first data set and the second data set so as to determine for each sampled position at least one first physical parameter;
combining the third data set and the fourth data set so as to determine for each sampled position at least one second physical parameter; and
combining the determined first physical parameter for each sampled position and the determined second physical parameter for each sampled position to form an output corrected physical parameter for each sampled position so as to at least partially correct for errors in the determined first and second physical parameters caused by intensity variations in the radiation used to generate the first, second, third and/or fourth data sets.

42. The method of claim 32, wherein the physical quantity comprises one or more aberrations of a projection system.

43. The method of claim 32, wherein the physical quantity comprises one or more intensities of a measured radiation, and the first, second, third and fourth physical parameters respectively correspond to first, second, third and fourth intensity values.

44. The method of claim 32, wherein combining the first, second, third and fourth data sets so as to determine the physical quantity comprises:
combining the first data set and the second data set so as to, for each sampling position, determine a first wavefront tilt coefficient in the second direction;
combining the third data set and the fourth data set so as to, for each sampling position, determine a second wavefront tilt coefficient in the second direction; and
combining the determined first wavefront tilt coefficients in the second direction for each sampling position and the determined second wavefront tilt coefficients in the second direction for each sampling position so as to form an output wavefront tilt coefficient in the second direction for each sampling position so as to at least partially correct for errors in the determined first wavefront tilt coefficients in the second direction and the determined second wavefront tilt coefficients in the second direction caused by intensity variations in the radiation used to generate the second data set and the fourth data set.

45. The method of claim 32, wherein the first direction and the second direction are each aligned at 45° relative to each of the first shearing direction and the second shearing direction.

46. The method of claim 32, wherein each measurement comprises:
illuminating the plurality of object plane patterning devices with first radiation;
forming, an image of each of the plurality of object plane patterning devices on a patterning device of a different one of the plurality of image plane sensors;
scanning at least one of the plurality of object plane patterning devices or the corresponding plurality of image plane sensors through a plurality of positions separated in a direction so as to generate an oscillating phase-scanning signal for each of the plurality of sampling positions; and
determining a phase of a harmonic of the oscillating signal at a plurality of positions on a radiation detector.

47. A computer readable medium carrying a non-transitory computer program comprising computer readable instructions configured to cause a computer to carry out a method of claim 32.

48. A computer apparatus comprising:
a memory storing processor readable instructions, and
a processor arranged to read and execute instructions stored in the memory, wherein the processor readable instructions comprise instructions arranged to control the computer to carry out the method of claim 32.

49. A measurement system for determining a physical quantity, the measurement system comprising:
a plurality of object plane patterning devices comprising a first set of patterning devices having a first orientation and a second set of patterning devices having a second orientation, the second orientation being different to the first orientation;
an illumination system arranged to illuminate the plurality of object plane patterning devices with radiation so as to form a plurality of first diffraction beams, the first diffraction beams from each of the first set of patterning devices being separated in a modulation direction corresponding to the first orientation of the gratings and the first diffraction beams from each of the second set of patterning devices being separated in a modulation direction corresponding to the second orientation of the gratings;
an image plane sensor comprising a patterning device and a radiation detector;
the illumination system being configured to form an image of each of the plurality of object plane patterning devices on the patterning device of the image plane sensor so as to form a plurality of second diffraction beams from each of the first diffraction beams;
a positioning apparatus configured to move the plurality of object plane patterning devices in a first direction or a second direction; and
a controller configured to carry out the method of claim 32.

50. A measurement system for determining a physical quantity, the measurement system comprising:
a plurality of object plane patterning devices comprising: a first set of patterning devices having a first orientation; and a second set of patterning devices having a second orientation, the second orientation being different to the first orientation;
an illumination system arranged to illuminate the plurality of object plane patterning devices with radiation so as to form a plurality of first diffraction beams, the first diffraction beams from each of the first set of patterning devices being separated in a modulation direction corresponding to the first orientation and the first diffraction beams from each of the second set of patterning devices being separated in a modulation direction corresponding to the second orientation;
a plurality of image plane sensors, each comprising a patterning device and each in communication with a radiation detector;
the illumination system being configured to form an image of each of the plurality of object plane patterning devices on the patterning device of the image plane sensor so as to form a plurality of second diffraction beams from each of the first diffraction beams;
a positioning apparatus configured to move at least one of the plurality of object plane patterning devices or the corresponding plurality of image plane sensors in a first direction or a second direction; and
a controller configured to carry out the method of claim 32.

51. A lithographic apparatus or a metrology tool comprising the measurement system of claim 49.
